(19) United States
(12) Patent Application Publication
(10) Pub. No.: US 2026/0088075 A1
(43) Pub. Date: Mar. 26, 2026

(54) APPARATUS FOR ROWHAMMER MITIGATION AND MEMORY DEVICE FOR ACTIVATION COUNTER MANAGEMENT

(71) Applicant: Intel Corporation, Santa Clara, CA (US)

(72) Inventor: Zion Siu-On KWOK, Burnaby (CA)

(21) Appl. No.: 19/410,021

(22) Filed: Dec. 5, 2025

(51) Int. Cl. G11C 11/406; G11C 11/4078

(52) U.S. Cl. CPC G11C 11/40615; G11C 11/40622; G11C 11/4078

(57) ABSTRACT

It is provided a non-transitory computer-readable medium storing instructions that, when executed by one or more processing circuitries of an apparatus, causing the one or more processing circuitries to perform locally on the apparatus a method. The method includes issuing periodic refresh commands to a memory device configured to perform refresh operations on a plurality of its memory regions. The method further comprises receiving the status value transmitted from the memory device. The method further comprises determining based on the status value whether a targeted-refresh condition is satisfied for one or more of the memory regions. The method further comprises transmitting, for each of the one or more memory regions, a number of targeted refresh commands to the memory device, the number being based on the status value of the corresponding memory region.

### BACKGROUND

Memory devices may require periodic refresh operations to maintain data integrity in storage cells where stored charge gradually dissipates over time. Some memory systems may face security challenges from repeated access patterns that can cause unintended effects in physically adjacent storage locations. Memory standards may implement counting mechanisms to track access activity and trigger mitigation operations when certain patterns are detected. Some approaches may use signaling mechanisms to communicate between memory devices and controllers when mitigation is needed, which may introduce latency and interrupt normal operations. Memory controllers may alternatively maintain tracking information locally, but such approaches may require additional circuitry that increases with memory capacity. There may be a need for improved mechanisms that provide effective mitigation.

### BRIEF DESCRIPTION OF THE FIGURES

Some examples of apparatuses and/or methods will be described in the following by way of example only, and with reference to the accompanying figures, in which

FIG. 1 illustrates a block diagram of an example of a non-transitory computer-readable medium;

FIG. 2 illustrates a block diagram of an example of an apparatus;

FIG. 3 illustrates a flowchart of an example of a method;

FIG. 4 illustrates a block diagram of an example of a memory device;

FIG. 5 illustrates a flowchart of an example of a method;

FIG. 6 illustrates a block diagram of an example of a memory device;

FIG. 7 illustrates a state machine diagram showing a non-sequential refresh sequence for resetting row activation counts:

FIG. 8 illustrates a state machine diagram showing the complete refresh sequence including end-of-bank handling for resetting row activation counts;

FIG. 9 illustrates a block diagram of an example of a memory device;

FIG. 10 illustrates a block diagram of an example of a memory device; and

FIG. 11 illustrates an example of a block diagram of an electronic apparatus.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

In the following description, specific details are set forth, but examples of the technologies described herein may be practiced without these specific details. Well-known circuits, structures, and techniques have not been shown in detail to avoid obscuring an understanding of this description. “An example/example,” “various examples/examples,” “some examples/examples,” and the like may include features, structures, or characteristics, but not every example necessarily includes the particular features, structures, or characteristics.

Some examples may have some, all, or none of the features described for other examples. “First,” “second,” “third,” and the like describe a common element and indicate different instances of like elements being referred to. Such adjectives do not imply element item so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform, or resource, even though the instructions contained in the software or firmware are not actively being executed by the system, device, platform, or resource.

The description may use the phrases “in an example/example,” “in examples/examples,” “in some examples/examples,” and/or “in various examples/examples,” each of which may refer to one or more of the same or different examples. Furthermore, the terms “comprising,” “including,” “having,” and the like, as used with respect to examples of the present disclosure, are synonymous.

In some examples, memory device (such as DRAM) standards may support a RowHammer mitigation scheme referred to as Per Row Activation Counting (PRAC). In conventional implementations, the memory device may track activation counts per row internally. When the activation counts exceed a threshold, the memory device may assert an ALERT pin to signal the memory controller that a refresh management (RFM) command needs to be issued. The assertion of the ALERT pin may trigger exception handling at the system-on-chip (SoC). To avoid frequent exception handling, the memory device standard may specify that the SoC should perform tracking per memory device bank. However, this tracking may be redundant because the memory device device already maintains per-row activation counters. The SoC may not want to add area overhead for maintaining bank-level tracking counters. The area overhead may scale with increasing memory capacity. Conventional solutions may make the tracking in the SoC optional, allowing the SoC to choose not to track if the ALERT exception handling performance penalty is acceptable, or alternatively to implement the tracking and accept the associated area overhead.

In some examples, an alternative approach may use periodic polling to provide information for optimal action by the memory controller. The memory controller may periodically read from the memory device the number of RFM commands that need to be issued for each bank. The read operation may be performed simultaneously with a refresh operation. The status value may be transmitted via the DQ bus during time when the DQ bus would otherwise be unused during refresh. This approach may eliminate ALERT signals for RowHammer mitigation and eliminate SOC tracking logic for bank activation counts. The approach may not increase command bandwidth because the refresh operation may perform two functions simultaneously. The approach may enable more fine-grained RowHammer mitigation by providing per-bank status information at frequent intervals, resulting in reduced command bandwidth overhead particularly for single-rank DIMM configurations.

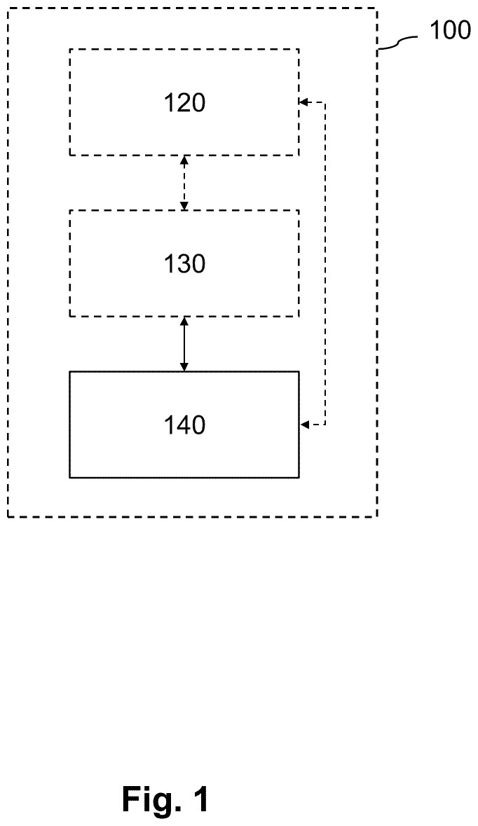

FIG. 1 illustrates a block diagram of an example of a non-transitory computer-readable medium 140. The non-transitory computer-readable medium 140 stores instructions that, when executed by one or more processing circuitries 130, causes the one or more processing circuitries 130 to perform a method. The one or more processing circuitries 130 may access the non-transitory computer-readable medium 140 via an interface circuitry 120. In some examples, the non-transitory computer-readable medium 140 may be included in an apparatus 100, which may also comprise the one or more processing circuitries 130. In some examples, the one or more processing circuitries 130 may be distributed over a plurality of apparatuses and may for example, access the non-transitory computer-readable medium 140 via the interface circuitry 120.

For example, the non-transitory computer-readable medium may refer to any tangible, physical medium capable of storing instructions, data, or other types of information for access by a computer, processor, or similar electronic device. The computer-readable medium may be non-transitory in that the medium may have a persistent or enduring form. The medium may retain stored information even when power is removed. The non-transitory computer-readable medium may comprise magnetic storage devices. Magnetic storage devices may include hard disk drives (HDDs) and magnetic tapes. Magnetic storage devices may store data using magnetic patterns. Magnetic storage devices may be used for long-term data storage in computers, servers, and backup systems. The non-transitory computer-readable medium may comprise optical storage media. Optical storage media may include compact discs (CDs), digital versatile discs (DVDs), and Blu-ray discs. Optical storage media may utilize laser technology to read and write data. Optical storage media may offer durability and longevity for storing software, media, and backups.

In some examples, the non-transitory computer-readable medium may comprise solid-state devices (SSDs). Solid-state devices may rely on flash memory technology. Solid-state devices may operate without moving parts. Solid-state devices may include USB flash drives, secure digital (SD) cards, or internal and external SSDs. Solid-state devices may provide fast read and write speeds and portability. In some examples, the non-transitory computer-readable medium may comprise non-volatile memory chips. Non-volatile memory chips may include read-only memory (ROM) and programmable ROM (PROM). Non-volatile memory chips may store firmware or embedded software. The non-volatile memory chips may be included in embedded systems and computers. In some examples, the non-transitory computer-readable medium may comprise phase-change memory (PCM). In some examples, the non-transitory computer-readable medium may comprise magnetoresistive RAM (MRAM). In some examples, the non-transitory computer-readable medium may comprise ferroelectric RAM (FeRAM). These memory technologies may offer persistent data storage with high reliability, speed, and power efficiency. These memory technologies may be suitable for applications requiring rapid access and data retention. Such applications may include mobile devices, high-performance computing, and industrial systems.

For example, the one or more processing circuitries 130 may access the non-transitory computer-readable medium 140 over the interface circuitry 120. For example, the one or more processing circuitries 130 may then execute the instructions stored on the non-transitory computer-readable medium 140. The execution of the instructions stored on the non-transitory computer-readable medium 140 causes the one or more processing circuitries 130 to the perform the method.

In some examples, the instructions stored on the non-transitory computer-readable medium 140 may comprise firmware or configuration code. The firmware or configuration code may configure hardware components of the one or more processing circuitries 130 to perform the method. The hardware components may include state machines, timing generators, command schedulers, or other logic circuits. The one or more processing circuitries 130 may comprise application-specific integrated circuit (ASIC) components that execute the refresh operations based on parameters defined by the instructions. The instructions may define refresh intervals, threshold values, status value formats, or other operational parameters. The execution of the instructions may cause the hardware components to autonomously perform periodic refresh operations according to the defined parameters. This configuration-based approach may enable efficient implementation where hardware state machines drive the periodic refresh operations while firmware defines the operational characteristics.

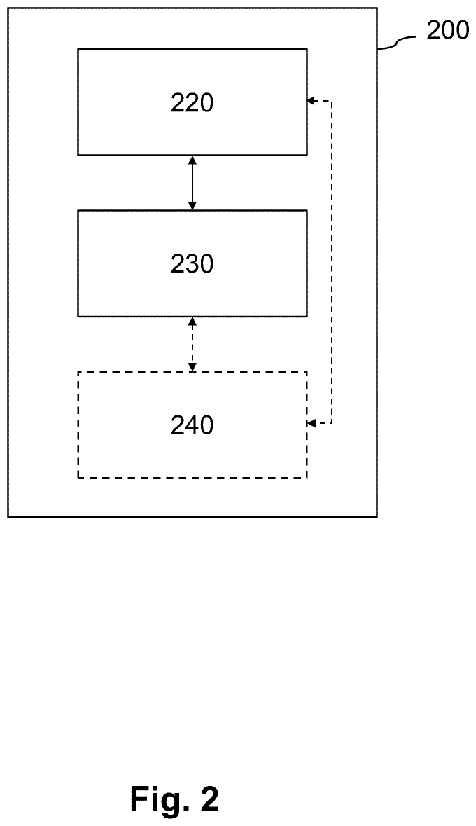

The method comprises issuing periodic refresh commands to a memory device configured to perform refresh operations on a plurality of its memory regions. Each memory region is a portion of the memory device comprising a plurality of memory rows. The at least one of the periodic refresh commands includes an indicator requesting a status value. In some examples, the one or more processing circuitries may be part of a memory controller 100 (see also for example apparatus 200 in FIG. 2). The memory controller may be configured to manage access operations to the memory device. The memory controller may be implemented as a standalone integrated circuit, as part of a system-on-chip (SoC), or as part of a processor. The memory controller may be coupled to the memory device via a memory bus. The memory bus may comprise command lines, address lines, and data lines. The memory controller may transmit commands and addresses to the memory device via the command lines and the address lines. The memory controller may exchange data with the memory device via the data lines.

In some examples, the memory device may be a semiconductor memory device configured to store data. The memory device may comprise volatile memory that requires periodic refresh to maintain stored data. The memory device may be implemented as a memory module, such as a dual in-line memory module (DIMM), or as a discrete memory chip. The memory device may receive commands from the memory controller and execute operations in response to the commands. In some examples, the memory device may comprise a dynamic random-access memory (DRAM) device. The DRAM device may store data in memory cells that comprise capacitors and access transistors. The stored charge in the capacitors may gradually leak over time, requiring periodic refresh operations to restore the charge. The DRAM device may be configured according to a DRAM standard. The DRAM standard may be a DDR5 standard, a DDR6 standard, or an LPDDR6 standard or the like.

In some examples, the memory device may comprise one or more memory arrays. Each memory array may comprise a plurality of memory cells arranged in rows and columns. The memory cells may be organized into a matrix structure. Each memory cell may store a single bit of data. Each memory cell may comprise a storage capacitor and an access transistor. The access transistor may control access to the storage capacitor. Each memory cell may be accessible by activating a corresponding row and selecting a corresponding column. Activating the row may enable the access transistors of all memory cells in that row. Selecting the column may connect the selected memory cell to a sense amplifier or to data input/output circuitry.

In some examples, each memory array may be organized into a plurality of memory regions. Each memory region may be a functionally and/or structurally distinct partition of the memory array. In some examples, the memory regions may be defined by dedicated hardware components associated with each region. The memory regions may be defined by separate control logic and separate data paths. Each memory region may operate independently from other memory regions. Independent operation may mean that each memory region can execute memory commands without waiting for other memory regions to complete their operations. Each memory region may be addressable using a region address or bank address as part of the overall memory address.

In some examples, each memory region may correspond to a bank of the memory device. Each bank may be an independently operable subdivision of the memory array. Each bank may function as a separate addressable unit within the memory device. The bank may be identified by a bank address. Commands directed to one bank may not affect the operational state of other banks. Each bank may maintain its own state information. The state information may include whether the bank is idle, whether a row is currently open, and which row is currently open. In some examples, each bank may comprise its own row decoder. The row decoder may be a hardware circuit dedicated to that bank. The row decoder may receive a row address from the command and address interface. The row decoder may decode the row address to select and activate the corresponding wordline within the bank. The activated wordline may connect the memory cells of the corresponding memory row to the sense amplifiers. Each bank may comprise its own column decoder. The column decoder may be a hardware circuit dedicated to that bank. The column decoder may receive a column address. The column decoder may decode the column address to select specific memory cells within the activated row for read or write operations.

In some examples, each bank may comprise its own sense amplifiers. The sense amplifiers may be analog circuits positioned adjacent to the memory cell array of the bank. The sense amplifiers may detect small voltage differences on the bitlines when a row is activated. The sense amplifiers may amplify these voltage differences to full logic levels. The sense amplifiers may also function as temporary storage to hold the data of the activated row. The data held in the sense amplifiers may be accessed for read operations or modified by write operations. The sense amplifiers may restore the data to the memory cells when the row is precharged.

In some examples, multiple banks may be operated in parallel to increase memory access throughput. The memory controller may issue activation commands to different banks simultaneously. The memory controller may interleave read and write operations across multiple banks. One bank may be activated and accessed while another bank is being precharged. This interleaving may hide latency and improve effective memory bandwidth. The parallel operation of multiple banks may allow the memory system to maintain high data transfer rates even when individual bank operations have inherent latencies.

In some examples, the memory device may comprise a DRAM device. In some examples, the DRAM device may comprise 16 banks, 32 banks, or another number of banks depending on the DRAM standard and device configuration. DDR4 devices may typically comprise 16 banks. DDR5 devices may typically comprise 32 banks. DDR6 devices may comprise 32 banks or a higher number. LPDDR6 devices may also comprise 32 banks. The number of banks may be specified as part of the memory device specification. A higher number of banks may provide more opportunities for parallel operation and may improve memory throughput.

In some examples, each memory region may comprise a plurality of memory rows. Each memory row may correspond to a row of memory cells in the memory array of that memory region. Each memory row may span horizontally across the memory array. Each memory row may comprise hundreds or thousands of memory cells. The number of memory cells in a memory row may depend on the page size and data width of the memory device. Each memory row may be uniquely identified by a row address within its memory region.

In some examples, each memory row may be accessed by providing a row address to the memory device. The row address may be provided as part of an activation command. The activation command may also include a bank address identifying the memory region containing the memory row. The memory device may route the activation command to the appropriate memory region based on the bank address. The row decoder of that memory region may decode the row address and activate the corresponding memory row.

In some examples, activating a memory row may open the memory row. Opening the memory row may involve driving the wordline associated with that memory row to an active voltage level. The active voltage level may turn on the access transistors of all memory cells in the memory row. Turning on the access transistors may connect the storage capacitors to the bitlines. The stored charge from the capacitors may flow onto the bitlines. The charge on the bitlines may create small voltage differences. The sense amplifiers may detect and amplify these voltage differences. The sense amplifiers may latch the amplified values. The latched values may represent the data stored in the memory row.

In some examples, the memory row may remain open until a precharge command closes the memory row. While the memory row is open, the data may be held in the sense amplifiers. While the memory row is open, read operations and write operations may access memory cells within the memory row. A read operation may retrieve data from the sense amplifiers. A write operation may modify the data in the sense amplifiers The precharge command may update the activation count for the row. The precharge command may also equalize the bitlines and prepare the bank for activating a different memory row.

The method comprises issuing the periodic refresh commands to the memory device. There may be issued one refresh command at a time to the memory device. Each refresh command may instruct the memory device to perform a refresh operation on one or more memory rows. The refresh operation may restore the charge in the memory cells to prevent data loss due to charge leakage. The memory controller may issue the periodic refresh commands at regular intervals. At least one of refresh command of the periodic refresh commands may comprise an indicator requesting a status value. The indicator may be a control signal or a bit field within the refresh command. The indicator may be encoded in the command packet transmitted from the memory controller to the memory device. The indicator may be set to a first logic state when the status value is requested and to a second logic state when the status value is not requested. For example, the indicator may be a single bit that is set to logic ‘1’ to request the status value and set to logic ‘0’ to perform a standard refresh without requesting the status value. The indicator may be included in every refresh command, in every second refresh command, in every third refresh command, or at another periodic interval.

In some examples, the status value may be a data value that indicates information about activation activity within the memory device. The status value may be generated by the memory device. The memory device may generate the status value by evaluating internal counters or registers. The status value may provide information to the memory controller without requiring the memory controller to maintain its own tracking counters. The status value may be transmitted from the memory device to the memory controller via the data lines of the memory bus.

In some examples, the memory device may generate the status value during the refresh operation. The memory device may aggregate per-row activation counters maintained for the plurality of memory rows of each memory region. Each per-row activation counter may track a number of times the corresponding memory row has been activated. The memory device may compare each per-row activation counter to a row-activation threshold. The memory device may determine, for each memory region, how many memory rows have per-row activation counters that exceed the row-activation threshold. The memory device may encode this information into the status value.

In some examples, the status value may be stored temporarily in an output buffer or register of the memory device. The status value may be prepared during the refresh operation and held in the output buffer until it is transmitted to the memory controller. The status value may be transmitted as part of a refresh response corresponding to the periodic refresh command that included the indicator. The transmission may occur via the data lines at a time determined by the memory protocol timing requirements.

In some examples, the status value may comprise, for each memory region, a multi-bit field representing a number of memory rows whose activation counts exceed the row-activation threshold. The multi-bit field may encode the count in a compressed or encoded format. The multi-bit field may allow the memory device to convey information about multiple memory rows using a limited number of bits. The status value may comprise one multi-bit field for each memory region in the memory device. For example, if the memory device comprises 32 banks, the status value may comprise 32 multi-bit fields, one for each bank.

In some examples, the multi-bit field may comprise a two-bit field. The two-bit field may represent whether none, one, two, or three or more memory rows have activation counts exceeding the row-activation threshold. The two-bit field may use the encoding ‘00’ to indicate that no memory rows exceed the row-activation threshold, ‘01’ to indicate that one memory row exceeds the row-activation threshold, ‘10’ to indicate that two memory rows exceed the row-activation threshold, and ‘11’ to indicate that three or more memory rows exceed the row-activation threshold. This encoding may allow the memory controller to determine an appropriate number of targeted refresh commands to issue for each memory region. The two-bit field may be compact and efficient, allowing the status value for all memory regions to fit within a single data packet. For example, a 64-bit data packet may carry two-bit fields for 32 memory regions. In some examples, a 1-bit field or 3-bit or 4-bit field or the like may be used.

In some examples, the method may comprise issuing a plurality of periodic refresh commands over time. The plurality may refer to multiple refresh commands issued sequentially at regular time intervals. Each refresh command may be a separate command issued (for example by the memory controller) at a different point in time. For example, a first refresh command may be issued, then after a refresh interval has elapsed, a second refresh command may be issued, then after the refresh interval has elapsed again, third refresh command may be issued and so forth. One refresh command at a time may be issued to the memory device. The memory device may receive the single refresh command and may internally execute refresh operations in response to that command. The single refresh command may cause the memory device to refresh at least one memory row in each of the plurality of memory regions. The memory device may refresh one memory row per memory region per refresh command. In some examples, multiple rows in a bank may be refreshed for each refresh command. For example, if the memory device comprises 32 banks, a single refresh command may cause the memory device to refresh 32 memory rows simultaneously, with one memory row being refreshed in each of the 32 banks. The memory device may maintain internal refresh address counters for each bank to track which row should be refreshed next in each bank. The memory device may increment these internal counters after each refresh operation.

In some examples, the periodic refresh commands may be issued at refresh intervals of below 5 microseconds. The refresh interval may be the time period between consecutive refresh commands. The refresh interval may be approximately 3.9 microseconds. The refresh interval may be selected to ensure timely refresh of all memory rows in the memory device. The memory cells may require regular refresh to compensate for charge leakage. The stored charge in the capacitors of the memory cells may gradually dissipate over time. Without periodic refresh, the stored data may be corrupted or lost. The refresh interval of below 5 microseconds may be sufficiently short to prevent data loss due to charge leakage. The refresh interval may also provide frequent opportunities to request status information from the memory device.

In some examples, at least one of the periodic refresh commands in the plurality may include the indicator requesting the status value. Other refresh commands in the plurality may not include the indicator. The memory controller may selectively include the indicator in certain refresh commands to obtain status information at desired intervals. For example, the status value may be received from the memory device during every second periodic refresh command cycle that includes the indicator. For example, the memory controller may include the indicator in every second refresh command issued. For example, the memory device may transmit the status value in response to each refresh command that includes the indicator. Alternatively, the status value may be received during every third periodic refresh command cycle that includes the indicator. For example, the memory controller may include the indicator in every third refresh command issued. For example, the status value may also be received during further periodic refresh command cycles, such as every fourth, fifth, or tenth refresh command cycle. The frequency of including the indicator may be configured based on system requirements.

In some examples, the memory device may transmit the status value as part of a refresh response corresponding to the periodic refresh command including the indicator. The refresh response may be a response packet or data transmission from the memory device to the memory controller. The refresh response may occur after the memory device has processed the refresh command. The status value may be transmitted via the data lines of the memory bus. The transmission may occur at a timing specified by the memory protocol. The memory controller may receive the status value and may use the status value to determine subsequent actions. The frequent refresh interval combined with periodic status value requests may enable effective monitoring of activation activity in the memory device. This monitoring may support RowHammer mitigation without requiring alert signals or maintaining tracking counters at the memory controller.

The method comprises further receiving, in response to the periodic refresh command including the indicator, the status value transmitted from the memory device, the status value indicating, for each memory region, a number of memory rows whose activation counts exceed a row-activation threshold. For example, the memory controller may receive the status value via the data lines of the memory bus connecting the memory controller to the memory device. The status value may be transmitted as part of a data packet. The data packet may have a predetermined size, such as 64 bits. The memory controller may read the status value from the data lines at a timing specified by the memory protocol. The reception may occur during a time window following the issuance of the refresh command with the indicator.

In some examples, the status value may indicate, for each memory region, a number of memory rows whose activation counts exceed a row-activation threshold. The status value may comprise, for each memory region, a multi-bit field representing the number of memory rows exceeding the row-activation threshold. The multi-bit field may comprise a two-bit field. The two-bit field may represent whether none, one, two, or three or more memory rows have activation counts exceeding the row-activation threshold. The status value may provide this information for all memory regions simultaneously. For example, if the memory device comprises 32 banks, the status value may comprise 32 two-bit fields, one for each bank, fitting within a 64-bit data packet.

In some examples, the row-activation threshold may be a predetermined count value. The row-activation threshold may define a limit above which a memory row is considered to have been activated excessively. The row-activation threshold may be set to protect against RowHammer attacks. A RowHammer attack may repeatedly activate a memory row to cause data corruption in adjacent victim rows. The row-activation threshold may be set to a value such as 661 activations. The row-activation threshold may be chosen based on the vulnerability characteristics of the memory cells. When a memory row is activated more times than the row-activation threshold, the memory row may pose a RowHammer risk to adjacent rows.

In some examples, the memory device may maintain activation counters for the memory rows. Each activation counter may track how many times the corresponding memory row has been activated. The memory device may compare each activation counter to the row-activation threshold. The memory device may determine, for each memory region, how many memory rows have activation counters exceeding the row-activation threshold. The memory device may encode this count into the multi-bit field for that memory region. For example, if Bank 5 has two memory rows with activation counts exceeding the row-activation threshold, the two-bit field for Bank 5 may be set to ‘10’. If Bank 12 has no memory rows exceeding the row-activation threshold, the two-bit field for Bank 12 may be set to ‘00’. If Bank 20 has four memory rows exceeding the row-activation threshold, the two-bit field for Bank 20 may be set to ‘11’ indicating three or more rows.

The method comprises further determining based on the status value whether a targeted-refresh condition is satisfied for one or more of the memory regions. The determining may be performed by the one or more processing circuitries of the memory controller. The one or more processing circuitries may evaluate the status value received from the memory device. The evaluation may involve analyzing the multi-bit field for each memory region. The targeted-refresh condition may be a condition that, when satisfied, indicates that targeted refresh operations should be performed for a memory region. The targeted-refresh condition may be satisfied when the status value indicates that one or more memory rows in a memory region have activation counts exceeding the row-activation threshold. The targeted-refresh condition may not be satisfied when the status value indicates that no memory rows in a memory region exceed the row-activation threshold.

In some examples, the one or more processing circuitries may check the multi-bit field for each memory region. For example, if the multi-bit field for a memory region has a value of ‘00’, the targeted-refresh condition may not be satisfied for that memory region. If the multi-bit field for a memory region has a value of ‘01’, ‘10’, or ‘11’, the targeted-refresh condition may be satisfied for that memory region. The one or more processing circuitries may identify which memory regions satisfy the targeted-refresh condition. The determination may be made independently for each memory region based on that memory region's corresponding multi-bit field in the status value. The one or more processing circuitries may then determine appropriate actions for each memory region based on whether the targeted-refresh condition is satisfied.

In some examples, determining that the targeted-refresh condition is satisfied may comprise identifying, based on the status value of each memory region, a number of targeted refresh commands to transmit to the memory device. The number of targeted refresh commands may be proportional to the number of memory rows whose activation counts exceed the row-activation threshold. The proportionality may mean that more targeted refresh commands are issued when more memory rows exceed the row-activation threshold. The proportionality may establish a relationship between the status value and the number of targeted refresh commands. The one or more processing circuitries may use a mapping or calculation to convert the status value into the number of targeted refresh commands. The identification may be performed for each memory region separately based on the multi-bit field corresponding to that memory region.

In some examples, the multi-bit field may directly indicate the number of targeted refresh commands to issue. If the two-bit field has a value of ‘00’, zero targeted refresh commands may be issued. If the two-bit field has a value of ‘01’ indicating one memory row exceeds the row-activation threshold, one targeted refresh command may be issued for that memory region. If the two-bit field has a value of ‘10’ indicating two memory rows exceed the row-activation threshold, two targeted refresh commands may be issued for that memory region. If the two-bit field has a value of ‘11’ indicating three or more memory rows exceed the row-activation threshold, four targeted refresh commands may be issued for that memory region. This mapping may provide proportionality while accounting for the compressed encoding of the status value. The one or more processing circuitries may apply this mapping to each memory region to determine the total number of targeted refresh commands to issue across all memory regions.

Determining whether the targeted-refresh condition is satisfied may be performed without maintaining activation counters for the memory regions at the one or more processing circuitries. The one or more processing circuitries may not store or track activation counts for individual memory rows or for memory regions. The one or more processing circuitries may not maintain counters that count how many times each memory row or each memory region has been activated. Instead, the one or more processing circuitries may rely entirely on the status value received from the memory device. The status value may provide sufficient information for the one or more processing circuitries to determine whether targeted refresh is needed. This approach may eliminate the need for dedicated counter hardware at the memory controller. This approach may reduce the area overhead and complexity of the memory controller. The memory device may maintain the activation counters internally, and may provide the aggregated status information to the memory controller via the status value.

The method comprises further in response to determining that the targeted-refresh condition is satisfied for one or more memory regions, transmitting, for each of the one or more memory regions, a number of targeted refresh commands to the memory device, the number being based on the status value of the corresponding memory region. The targeted refresh commands may be issued via the command lines of the memory bus. The targeted refresh commands may be transmitted after receiving and evaluating the status value. The targeted refresh commands may be transmitted for each of the one or more memory regions for which the targeted-refresh condition is satisfied. Memory regions for which the targeted-refresh condition is not satisfied may not receive targeted refresh commands.

In some examples, a number of targeted refresh commands may be transmitted for each of the one or more memory regions. The number of targeted refresh commands transmitted for a particular memory region may be based on the status value of the corresponding memory region. The number may be determined from the multi-bit field corresponding to that memory region in the status value. Different memory regions may receive different numbers of targeted refresh commands depending on their respective status values. A memory region with a status value indicating one row exceeding the row-activation threshold may receive one targeted refresh command. A memory region with a status value indicating two rows exceeding the row-activation threshold may receive two targeted refresh commands. A memory region with a status value indicating three or more rows exceeding the row-activation threshold may receive three or four targeted refresh commands.

In some examples, each targeted refresh command may be directed to a specific memory region. Each targeted refresh command may include a bank address identifying the memory region to which the command is directed. The memory device may receive the targeted refresh command and may execute a targeted refresh operation in the specified memory region. The targeted refresh operation may refresh victim memory rows adjacent to memory rows that have excessive activation counts. This may mitigate potential RowHammer effects on the victim rows.

In some examples, the memory device may reset the status value of a memory region after execution of the targeted refresh commands directed to that memory region. Resetting the status value may mean setting the multi-bit field for that memory region back to ‘00’. The reset may indicate that the memory rows that exceeded the row-activation threshold have been addressed by the targeted refresh operations. The reset may allow the memory device to begin tracking new accumulations of activation counts. The memory device may perform the reset after completing the targeted refresh operations for the memory region. The memory device may increment the status value again if additional memory rows exceed the row-activation threshold during subsequent normal operation. This cyclical process of status value generation, transmission, targeted refresh, and reset may provide continuous RowHammer protection.

The above method may enable effective RowHammer mitigation without requiring to maintain activation counters for the memory regions, thereby eliminating area overhead at the memory controller that would otherwise scale with increasing memory capacity. The method may further eliminate the need to process RowHammer-alert signals from the memory device, thereby avoiding exception handling that can impact system performance and stop traffic across multiple ranks or subchannels. The method may not increase command bandwidth because the refresh operation can simultaneously perform the refresh and provide the status value without requiring additional dedicated commands. The method may enable more fine-grained RowHammer mitigation by providing per-region status information at frequent intervals, resulting in reduced command bandwidth overhead particularly for single-rank memory configurations. For example, a frequent polling interval may provide timely detection of activation threshold violations, allowing the memory controller to issue targeted refresh commands proactively before RowHammer attacks can cause data corruption in victim rows.

In some examples, the method may further comprise transmitting the periodic refresh commands and the targeted refresh commands without increasing command bandwidth relative to standard refresh operation. For example, standard refresh operation may refer to conventional refresh procedures that do not include RowHammer mitigation features. The disclosed method may achieve the same or similar command bandwidth as standard refresh operation despite adding RowHammer protection functionality. The periodic refresh commands with the indicator may not consume additional command bandwidth because the indicator may be integrated into existing refresh command structures. The status value may be transmitted via data lines during time periods when the data lines would otherwise be unused during refresh operations. The targeted refresh commands may replace or be counted as part of the refresh operations that would be needed anyway for memory maintenance. The method may efficiently utilize existing command and data bandwidth resources without requiring additional bandwidth allocation for RowHammer mitigation. This efficiency may allow the method to provide RowHammer protection without degrading overall memory system performance or requiring modifications to command scheduling constraints.

In some examples, the method may further comprise refraining from processing a RowHammer-alert signal from the memory device. Refraining from processing may mean that the one or more processing circuitries do not monitor, receive, or respond to a RowHammer-alert signal. The RowHammer-alert signal may be a signal that conventional memory devices assert when RowHammer conditions are detected internally. Processing such a signal may require exception handling routines that can disrupt normal memory operations. The method may avoid the need for such alert signals by proactively obtaining status information through the periodic refresh commands with the indicator. The one or more processing circuitries may determine when targeted refresh is needed based on the status value rather than waiting for an alert signal. This proactive approach may eliminate the performance penalties associated with alert signal processing. The memory device may omit transmission of the RowHammer-alert signal entirely, thereby simplifying the interface between the memory controller and the memory device. The elimination of alert signals may reduce latency spikes and improve overall system responsiveness during RowHammer mitigation operations.

In some examples, the method may further comprise causing the memory device to refresh one or more victim memory rows adjacent to a memory row whose activation count exceeds the row-activation threshold for each targeted refresh command. The causing may be accomplished by transmitting the targeted refresh commands to the memory device. Each targeted refresh command may instruct the memory device to perform a targeted refresh operation. The targeted refresh operation may refresh victim memory rows rather than the memory row that has the excessive activation count. The victim memory rows may be memory rows that are physically adjacent to the memory row with the excessive activation count. Physical adjacency may mean that the victim memory rows are located immediately next to the excessively activated memory row in the memory array. The victim memory rows may be at risk of data corruption due to the RowHammer effect caused by repeated activation of the adjacent memory row.

In some examples, the memory device may identify which memory row has exceeded the row-activation threshold. The memory device may determine the addresses of the victim memory rows adjacent to that memory row. The adjacent victim memory rows may include the memory row immediately above and the memory row immediately below the excessively activated memory row. The memory device may perform refresh operations on these victim memory rows in response to the targeted refresh command. The refresh operations may restore the charge in the memory cells of the victim memory rows. This restoration may counteract any charge leakage or disturbance caused by the repeated activation of the adjacent memory row. By refreshing the victim memory rows, the method may prevent data corruption that could otherwise result from RowHammer attacks. Each targeted refresh command may cause the memory device to refresh the victim rows for one memory row that exceeded the row-activation threshold, thereby providing protection proportional to the detected RowHammer risk.

Further details and aspects are mentioned in connection with the examples described below. The example shown in FIG. 1 may include one or more optional additional features corresponding to one or more aspects mentioned in connection with the proposed concept or one or more examples described above (e.g., FIG. 1) or below (e.g., FIGS. 2-11).

FIG. 2 illustrates a block diagram of an example of an apparatus 200 or device 200. For example, the apparatus 200 may implement or be part of a memory controller. The apparatus 200 comprises circuitry that is configured to provide the functionality of the apparatus 200. For example, the apparatus 200 of FIG. 2 comprises interface circuitry 220, processing circuitry 230 and (optional) storage circuitry 240. For example, the processing circuitry 230 may be coupled with the interface circuitry 220 and optionally with the storage circuitry 240.

For example, the processing circuitry 230 may be configured to provide the functionality of the apparatus 200, in conjunction with the interface circuitry 220. For example, the interface circuitry 220 is configured to exchange information, e.g., with other components inside or outside the apparatus 200 and the storage circuitry 240. Likewise, the device 200 may comprise means that is/are configured to provide the functionality of the device 200.

The components of the device 200 are defined as component means, which may correspond to, or implemented by, the respective structural components of the apparatus 200. For example, the device 200 of FIG. 2 comprises means for processing 230, which may correspond to or be implemented by the processing circuitry 230, means for communicating 220, which may correspond to or be implemented by the interface circuitry 220, and (optional) means for storing information 240, which may correspond to or be implemented by the storage circuitry 240. In the following, the functionality of the device 200 is illustrated with respect to the apparatus 200. Features described in connection with the apparatus 200 may thus likewise be applied to the corresponding device 200.

In general, the functionality of the processing circuitry 230 or means for processing 230 may be implemented by the processing circuitry 230 or means for processing 230 executing machine-readable instructions. Accordingly, any feature ascribed to the processing circuitry 230 or means for processing 230 may be defined by one or more instructions of a plurality of machine-readable instructions. The apparatus 200 or device 200 may comprise the machine-readable instructions, e.g., within the storage circuitry 240 or means for storing information 240.

The interface circuitry 220 or means for communicating 220 may correspond to one or more inputs and/or outputs for receiving and/or transmitting information, which may be in digital (bit) values according to a specified code, within a module, between modules or between modules of different entities. For example, the interface circuitry 220 or means for communicating 220 may comprise circuitry configured to receive and/or transmit information.

For example, the processing circuitry 230 or means for processing 230 may be implemented using one or more processing units, one or more processing devices, any means for processing, such as a processor, a computer or a programmable hardware component being operable with accordingly adapted software. In other words, the described function of the processing circuitry 230 or means for processing 230 may as well be implemented in software, which is then executed on one or more programmable hardware components. Such hardware components may comprise a general-purpose processor, a Digital Signal Processor (DSP), a micro-controller, etc.

For example, the storage circuitry 240 or means for storing information 240 may comprise at least one element of the group of a computer readable storage medium, such as a magnetic or optical storage medium, e.g., a hard disk drive, a flash memory, Floppy-Disk, Random Access Memory (RAM), Read Only Memory (ROM), Programmable Read Only Memory (PROM), Erasable Programmable Read Only Memory (EPROM), an Electronically Erasable Programmable Read Only Memory (EEPROM), or a network storage.

For example, the memory may have an architecture where multiple memory dies are vertically stacked on top of each other and interconnected using through-silicon vias (TSVs). The stacked memory dies may be mounted on a base die. The apparatus 200 may be implemented as a memory controller located on the base die of a stack. The memory controller on the base die may communicate with the stacked memory dies via the TSVs. The memory controller may issue periodic refresh commands to memory devices in the stacked dies, receive status values from the memory devices, determine targeted-refresh conditions, and transmit targeted refresh commands based on the status values. This integration of the memory controller on the base die may reduce communication latency and simplify system architecture. For example, the apparatus 200 may be implemented in a High Bandwidth Memory (HBM) configuration.

The processing circuitry 230 is configured to issue periodic refresh commands to a memory device configured to perform refresh operations on a plurality of its memory regions. Each memory region is a portion of the memory device comprising a plurality of memory rows. The at least one of the periodic refresh commands includes an indicator requesting a status value. The processing circuitry 230 is further configured to receive, in response to the periodic refresh command including the indicator, the status value transmitted from the memory device. The status value indicates, for each memory region, a number of memory rows whose activation counts exceed a row-activation threshold. The processing circuitry 230 is further configured to determine based on the status value whether a targeted-refresh condition is satisfied for one or more of the memory regions. The processing circuitry 230 is further configured to, in response to determining that the targeted-refresh condition is satisfied for one or more memory regions, transmit, for each of the one or more memory regions, a number of targeted refresh commands to the memory device, the number being based on the status value of the corresponding memory region.

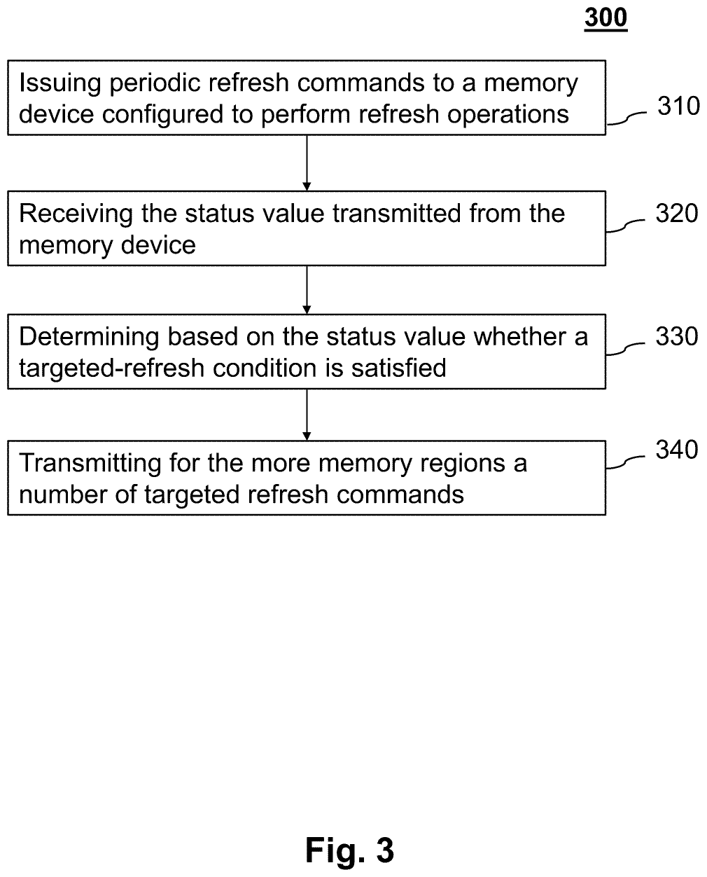

Further details and aspects are mentioned in connection with the examples described above or below. The example shown in FIG. 2 may include one or more optional additional features corresponding to one or more aspects mentioned in connection with the proposed concept or one or more examples described above (e.g., FIG. 1) or below (e.g., FIGS. 3-11).

FIG. 3 illustrates a flowchart of an example of a method 300. The method 300 may, for instance, be performed by an apparatus as described herein, such as apparatus 100 or apparatus 200. The method 300 comprises issuing 310 periodic refresh commands to a memory device configured to perform refresh operations on a plurality of its memory regions, each memory region being a portion of the memory device comprising a plurality of memory rows, wherein at least one of the periodic refresh commands includes an indicator requesting a status value. The method 300 comprises further receiving 320, in response to the periodic refresh command including the indicator, the status value transmitted from the memory device, the status value indicating, for each memory region, a number of memory rows whose activation counts exceed a row-activation threshold. The method 300 comprises further determining 330 based on the status value whether a targeted-refresh condition is satisfied for one or more of the memory regions. The method 300 comprises further in response to determining that the targeted-refresh condition is satisfied for one or more memory regions, transmitting 340 for each of the one or more memory regions, a number of targeted refresh commands to the memory device, the number being based on the status value of the corresponding memory region.

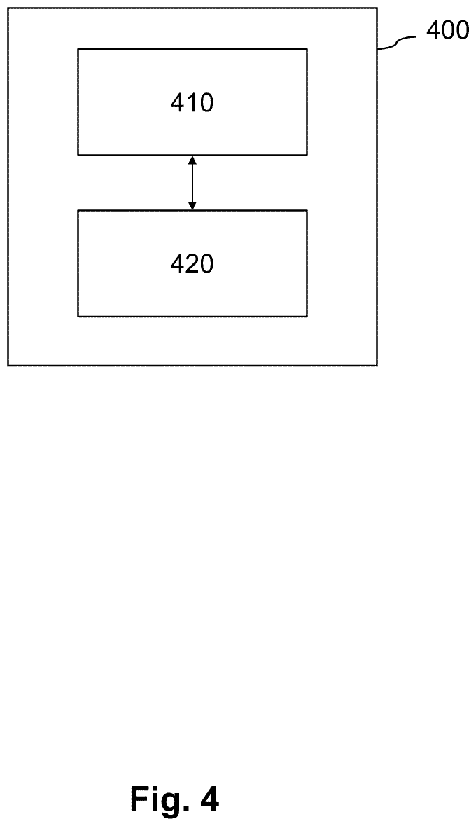

Further details and aspects are mentioned in connection with the examples described above or below. The example shown in FIG. 3 may include one or more optional additional features corresponding to one or more aspects mentioned in connection with the proposed concept or one or more examples described above (e.g., FIGS. 1-2) or below (e.g., FIGS. 4-11).

### Memory Device

FIG. 4 illustrates a block diagram of an example of a memory device 400. For example, the memory device 400 described with reference to FIG. 4 may incorporate elements, components, and concepts that have been described above with reference to FIGS. 1 to 3. The terminology, definitions, and technical details established in the preceding descriptions may apply equally to the memory device 400 unless explicitly stated otherwise. As described above with regards to FIG. 2, for example, the memory device may have an architecture where multiple memory dies are vertically stacked on top of each other and interconnected using TSVs. The stacked memory dies may be mounted on a base die. The memory controller located on the base die of a stack. The memory controller on the base die may communicate with the stacked memory dies via the TSVs. The memory controller may issue periodic refresh commands to memory devices in the stacked dies, receive status values from the memory devices, determine targeted-refresh conditions, and transmit targeted refresh commands based on the status values. This integration of the memory controller on the base die may reduce communication latency and simplify system architecture.

For example, the memory device 400 comprises circuitry that is configured to provide the functionality of the memory device 400. The memory device 400 comprises a memory array 410 organized into a plurality of memory regions. The memory device 400 further comprises control circuitry 420. The components of the memory device 400 are defined as component means, which may correspond to, or implemented by, the respective structural components of the memory device 400. For example, the memory device 400 comprises means for processing 420, which may correspond to or be implemented by the control circuitry 420 and optional means for communicating.

In some examples, the control circuitry 420 may be hardware circuitry configured to control operations of the memory device. The control circuitry 420 may comprise digital logic circuits implemented in semiconductor technology. The control circuitry 420 may include finite state machines that manage command execution sequences and timing. The control circuitry 420 may include command decoders that interpret commands received from the memory controller. The control circuitry 420 may include timing generators that produce control signals with precise timing relationships. The control circuitry 420 may include address decoders that route operations to appropriate memory regions. The control circuitry 420 may include counter circuits that track refresh addresses, activation counts, and other operational parameters. The control circuitry 420 may include comparator circuits that evaluate counter values against thresholds. The control circuitry 420 may include multiplexers and data path control logic that route data between different functional blocks. The control circuitry 420 may be hardwired logic that performs predefined operations in response to commands and internal states. The control circuitry 420 may be distributed across different functional blocks of the memory device or may be centralized in a control unit.

In some examples, the memory device may be a semiconductor memory device configured to store data. The memory device may comprise volatile memory that requires periodic refresh to maintain stored data. The memory device may be a discrete integrated circuit chip or may be part of a memory module. The memory device may be implemented as a dual in-line memory module (DIMM), a small outline DIMM (SODIMM), a compression attached memory module (CAMM), a small outline compression attached memory module (SOCAMM), or as an individual memory chip mounted on a circuit board. The memory device may communicate with a memory controller via electrical connections. The electrical connections may include command lines, address lines, and data lines. The memory device may receive commands and addresses from the memory controller. The memory device may transmit data to and receive data from the memory controller.

In some examples, the memory device may comprise a dynamic random-access memory (DRAM) device. The DRAM device may store data in memory cells that comprise capacitors and access transistors. The stored charge in the capacitors may gradually leak over time, requiring periodic refresh operations to restore the charge. The DRAM device may be configured according to a DRAM standard. The DRAM standard may be a DDR5 standard, a DDR6 standard, an LPDDR6 standard, or another DRAM standard. The memory device may comply with timing, electrical, and protocol specifications defined by the DRAM standard.

In some examples, the memory device may comprise one or more memory arrays. Each memory array may comprise a plurality of memory cells arranged in rows and columns. The memory cells may be organized into a matrix structure. Each memory cell may store a single bit of data. Each memory cell may comprise a storage capacitor and an access transistor. The access transistor may control access to the storage capacitor. Each memory cell may be accessible by activating a corresponding row and selecting a corresponding column. Activating the row may enable the access transistors of all memory cells in that row. Selecting the column may connect the selected memory cell to a sense amplifier or to data input/output circuitry.

In some examples, each memory array may be organized into a plurality of memory regions. Each memory region may be a functionally and structurally distinct partition of the memory array. The memory regions may be defined by dedicated hardware components associated with each region. The memory regions may be defined by separate control logic and separate data paths. Each memory region may operate independently from other memory regions. Independent operation may mean that each memory region can execute memory commands without waiting for other memory regions to complete their operations. Each memory region may be addressable using a region address or bank address as part of the overall memory address.

In some examples, each memory region may correspond to a bank of the DRAM device. Each bank may be an independently operable subdivision of the memory array. Each bank may function as a separate addressable unit within the memory device. The bank may be identified by a bank address. Commands directed to one bank may not affect the operational state of other banks. Each bank may maintain its own state information. The state information may include whether the bank is idle, whether a row is currently open, and which row is currently open.

In some examples, each bank may comprise its own row decoder. The row decoder may be a hardware circuit dedicated to that bank. The row decoder may receive a row address from command and address signals. The row decoder may decode the row address to select and activate the corresponding wordline within the bank. The activated wordline may connect the memory cells of the corresponding memory row to the sense amplifiers. Each bank may comprise its own column decoder. The column decoder may be a hardware circuit dedicated to that bank. The column decoder may receive a column address. The column decoder may decode the column address to select specific memory cells within the activated row for read or write operations.

In some examples, each bank may comprise its own sense amplifiers. The sense amplifiers may be analog circuits positioned adjacent to the memory cell array of the bank. The sense amplifiers may detect small voltage differences on the bitlines when a row is activated. The sense amplifiers may amplify these voltage differences to full logic levels. The sense amplifiers may also function as temporary storage to hold the data of the activated row. The data held in the sense amplifiers may be accessed for read operations or modified by write operations. The sense amplifiers may restore the data to the memory cells when the row is precharged.

In some examples, multiple banks may be operated in parallel. Different banks may execute different commands simultaneously or in an overlapped manner. One bank may be activated and accessed while another bank is being precharged. One bank may undergo a refresh operation while another bank performs a read operation. This parallel operation may increase overall memory throughput. The DRAM device may comprise 16 banks, 32 banks, or another number of banks depending on the DRAM standard and device configuration. DDR4 devices may typically comprise 16 banks. DDR5 devices may typically comprise 32 banks. DDR6 devices may comprise 32 banks or a higher number. LPDDR6 devices may also comprise 32 banks.

In some examples, each memory region may comprise a plurality of memory rows. Each memory row may correspond to a row of memory cells in the memory array of that memory region. Each memory row may span horizontally across the memory array. Each memory row may comprise hundreds or thousands of memory cells. The number of memory cells in a memory row may depend on the page size and data width of the memory device. Each memory row may be uniquely identified by a row address within its memory region. Each memory row may be access

The control circuitry 420 is configured to perform periodic refresh operations on the plurality of memory regions in response to refresh commands received from a memory controller (for example, apparatus 100 or 200). The one or more of the refresh commands include an indicator requesting a status value. The refresh operation may restore the charge in the memory cells to prevent data loss due to charge leakage. The control circuitry 420 may receive a refresh command via the command lines from the memory controller. The refresh command may cause the control circuitry to initiate refresh operations across the memory regions. A single refresh command may cause the control circuitry 420 to refresh at least one memory row in each of the plurality of memory regions (e.g., banks). The control circuitry 420 may refresh one memory row per memory region per refresh command. For example, if the memory device comprises 32 banks, a single refresh command may cause the control circuitry to refresh 32 memory rows simultaneously, with one memory row being refreshed in each of the 32 banks. The control circuitry 420 may maintain internal refresh address counters for each bank. The refresh address counters may track which row should be refreshed next in each bank. The control circuitry may increment the refresh address counters after each refresh operation.

In some examples, the refresh commands may be received periodically from the memory controller. The periodic reception may mean that refresh commands arrive at regular time intervals. The control circuitry may perform the refresh operations in response to each received refresh command. The periodic refresh operations may collectively maintain the data integrity of all memory rows in the memory device. The memory cells may require regular refresh to compensate for charge leakage. Without periodic refresh, the stored data may be corrupted or lost. The periodic refresh operations may be executed at refresh intervals below 5 microseconds. The refresh interval may be the time period between consecutive refresh operations. For example, the refresh interval may be approximately 3.9 microseconds. The refresh interval may be determined by the rate at which the memory controller issues refresh commands. The refresh interval of below 5 microseconds may be sufficiently short to prevent data loss due to charge leakage in the memory cells.

In some examples, one or more of the refresh commands may include an indicator requesting a status value. The indicator may be a control signal or a bit field within the refresh command. The indicator may be encoded in the command packet received from the memory controller. The control circuitry 420 may decode the refresh command to determine whether the indicator is present. If the indicator is present, the control circuitry may prepare and transmit the status value in addition to performing the refresh operation. If the indicator is not present, the control circuitry 420 may perform the refresh operation without transmitting the status value. The indicator may be included in every refresh command, in every second refresh command, in every third refresh command, or at another periodic interval.

In some examples, the status value may be a data value that indicates information about activation activity within the memory device. The status value may indicate, for each memory region, a number of memory rows whose activation counters exceed a row-activation threshold. The status value may provide this information for all memory regions simultaneously in a compact format. The status value may comprise, for each memory region, a multi-bit field representing a number of memory rows whose activation counters exceed the row-activation threshold. The multi-bit field may encode the count in a compressed or encoded format. The multi-bit field may allow the memory device to convey information about multiple memory rows using a limited number of bits. The status value may comprise one multi-bit field for each memory region in the memory device. For example, if the memory device comprises 32 banks, the status value may comprise 32 multi-bit fields, one for each bank.

In some examples, the multi-bit field may comprise a two-bit field. The two-bit field may represent whether none, one, two, or three or more memory rows have activation counters exceeding the row-activation threshold. The two-bit field may use the encoding ‘00’ to indicate that no memory rows exceed the row-activation threshold. The two-bit field may use the encoding ‘01’ to indicate that one memory row exceeds the row-activation threshold. The two-bit field may use the encoding ‘10’ to indicate that two memory rows exceed the row-activation threshold. The two-bit field may use the encoding ‘11’ to indicate that three or more memory rows exceed the row-activation threshold. This encoding may provide sufficient information for the memory controller to determine an appropriate number of targeted refresh commands to issue for each memory region. The two-bit field may be compact and efficient. A 64-bit data packet may carry two-bit fields for 32 memory regions, allowing the entire status value to be transmitted in a single data transfer.

The control circuitry 420 may be configured to maintain, for each memory row within each memory region, an activation counter indicating a number of activations of that memory row. The activation counter may be implemented by a digital counter circuit or register in the memory device that stores a count value. The count value may represent how many times the corresponding memory row has been activated. Each memory row may have its own dedicated activation counter. The control circuitry 420 may allocate storage for the activation counters in register arrays or memory structures within the memory device. For example, if a memory region comprises 65,536 memory rows, the control circuitry may maintain 65,536 activation counters for that memory region. The activation counters may be implemented as hardware counters or as values stored in a dedicated tracking memory. The activation counters may be updated in real-time as memory operations occur.

In some examples, the control circuitry 420 may increment an activation counter when the corresponding memory row is activated. The control circuitry may detect an activation command directed to a specific memory row. The activation command may include a bank address and a row address. The control circuitry 420 may identify the activation counter corresponding to that bank address and row address. The control circuitry may increment the activation counter by one or more counts. The activation counters may track activation activity to enable RowHammer detection and mitigation. A memory row that is activated excessively may pose a RowHammer risk to adjacent victim rows. By maintaining activation counters, the control circuitry may identify which memory rows have been activated beyond a safe threshold. The control circuitry may use the activation counter values to generate the status value that is transmitted to the memory controller. The activation counters may be reset periodically or after targeted refresh operations have addressed the RowHammer risk.

In some examples, the control circuitry 420 may be further configured to increment each activation counter in response to a row activation command. The control circuitry 420 may receive a row activation command from the memory controller. The row activation command may specify a bank address and a row address identifying a particular memory row. The control circuitry 420 may decode the row activation command and identify the corresponding activation counter for that memory row. The control circuitry 420 may increment the activation counter by one count in response to the row activation command. This incrementation may occur each time the memory row is activated. The control circuitry 420 may track the cumulative number of activations over time. When the activation counter reaches or exceeds the row-activation threshold, the memory row may be identified as posing a potential RowHammer risk.

In some examples, the control circuitry 420 may be further configured to increment each activation counter based on an open-row duration that exceeds a predetermined time. The open-row duration may be the time period between activation of the memory row and precharge of the memory row. The memory row may be kept open to allow multiple read or write operations without repeated activation and precharge cycles. The control circuitry 420 may measure or track the open-row duration. If the open-row duration exceeds a predetermined time threshold, the control circuitry may increment the activation counter by additional counts. In some examples, the predetermined time may be approximately 225 nanoseconds. A memory row kept open for 225 nanoseconds may be counted as approximately three activations. In some examples, the control circuitry 420 may add one count if the open-row duration is less than 75 nanoseconds, two counts if the open-row duration is between 75 and 150 nanoseconds, and three counts if the open-row duration exceeds 150 nanoseconds. This approach may account for the fact that a memory row kept open for an extended period may cause similar or greater electrical disturbance to adjacent victim rows as multiple brief activation events. Accounting for open-row duration may provide more accurate RowPress attack risk assessment and more effective mitigation.

The control circuitry 420 may be configured to determine, for each memory region. The status value indicating a number of memory rows whose activation counters exceed a row-activation threshold. The row-activation threshold may be a predetermined count value. The row-activation threshold may define a limit above which a memory row is considered to have been activated excessively. The row-activation threshold may be set to protect against RowHammer attacks. The row-activation threshold may be set to a value such as 661 activations. The row-activation threshold may be chosen based on the vulnerability characteristics of the memory cells and the refresh interval timing. The row-activation threshold may be stored in a configuration register within the memory device. The row-activation threshold may be programmed during initialization or may be fixed during manufacturing.

In some examples, the control circuitry 420 may compare each activation counter to the row-activation threshold to determine the status value. The control circuitry 420 may iterate through the activation counters for each memory row in a memory region. For each activation counter, the control circuitry 420 may determine whether the count value exceeds the row-activation threshold. The control circuitry 420 may count how many memory rows in the memory region have activation counters exceeding the row-activation threshold. The control circuitry 420 may encode this count into the multi-bit field for that memory region. For example, if two memory rows in Bank 5 have activation counters exceeding the row-activation threshold, the control circuitry 420 may set the two-bit field for Bank 5 to ‘10’. If no memory rows in Bank 12 exceed the row-activation threshold, the control circuitry may set the two-bit field for Bank 12 to ‘00’. If four or more memory rows in Bank 20 exceed the row-activation threshold, the control circuitry may set the two-bit field for Bank 20 to ‘11’. The control circuitry may perform this determination for all memory regions and assemble the complete status value comprising the multi-bit fields for all memory regions. The determination may occur during or immediately after the refresh operation when a refresh command with the indicator is received.

The control circuitry 420 may be configured to transmit the status value to the memory controller in response to receiving the one or more refresh commands including the indicator. The control circuitry 420 may decode a received refresh command to determine whether the indicator is present. If the indicator is present, the control circuitry 420 may prepare the status value for transmission. The control circuitry 420 may assemble the status value by combining the multi-bit fields from all memory regions into a single data packet. The control circuitry 420 may output the status value onto the data lines of the memory bus. The transmission may occur at a timing specified by the memory protocol. The timing may be coordinated with the refresh operation to avoid conflicts with other data transfers. The status value may be transmitted as part of a refresh response corresponding to the periodic refresh command that included the indicator.

In some examples, the transmission of the status value may provide the memory controller with information needed for RowHammer mitigation without requiring the memory controller to maintain its own tracking counters. The control circuitry 420 may transmit the status value via the data lines during a time period when the data lines would otherwise be unused during the refresh operation. This may allow the status value transmission to occur without increasing command bandwidth or interfering with normal memory operations. The memory controller may receive the status value and may use the status value to determine which memory regions require targeted refresh operations. The frequent transmission of status values may enable proactive RowHammer mitigation. The memory controller may issue targeted refresh commands before RowHammer attacks can cause data corruption. The transmission may occur only when the indicator is present in the refresh command, allowing the memory controller to control the frequency of status value updates based on system requirements.

In some examples, the control circuitry 420 may be further configured to transmit the status value to the memory controller only during every second, third, or further periodic refresh command cycle that includes the indicator. The control circuitry 420 may track which refresh commands include the indicator. The control circuitry 420 may transmit the status value only when the indicator is present in the received refresh command. The memory controller may include the indicator in every second refresh command, in every third refresh command, or at another periodic interval. The control circuitry 420 may respond to each refresh command with the indicator by transmitting the status value. The control circuitry 420 may not transmit the status value when the indicator is absent. This selective transmission may reduce the frequency of data transfers on the data lines. For example, if the indicator is included in every second refresh command, the control circuitry may transmit the status value approximately every 7.8 microseconds when the refresh interval is 3.9 microseconds.

In some examples, the selective transmission may balance the need for timely status updates against data bus utilization. Transmitting the status value with every refresh command may consume excessive data bandwidth. Transmitting the status value too infrequently may delay detection of RowHammer conditions. By transmitting the status value during every second, third, or further refresh command cycle, the control circuitry may provide sufficiently frequent updates for effective RowHammer mitigation while minimizing data bus overhead. The frequency of status value transmission may be configurable based on system requirements. Systems with higher RowHammer risk may configure more frequent transmission. Systems with lower risk may configure less frequent transmission. The control circuitry 420 may implement this selective transmission by checking for the presence of the indicator in each received refresh command and conditionally executing the status value transmission logic only when the indicator is detected.

The control circuitry 420 may be configured to reset the status value of a memory region when one or more targeted refresh commands directed to that memory region are executed. The control circuitry 420 may receive a targeted refresh command from the memory controller. The targeted refresh command may include a bank address identifying the memory region to which the command is directed. The control circuitry 420 may execute a targeted refresh operation in the specified memory region in response to the targeted refresh command. After executing the targeted refresh operation, the control circuitry 420 may reset the status value for that memory region. Resetting the status value may mean setting the multi-bit field for that memory region back to ‘00’. The control circuitry may clear the indication that memory rows in that memory region exceed the row-activation threshold. The reset may occur after one targeted refresh command or after multiple targeted refresh commands have been executed for the memory region, depending on how many rows exceeded the threshold.

In some examples, resetting the status value may indicate that the RowHammer risk for that memory region has been addressed by the targeted refresh operations. The targeted refresh operations may have refreshed the victim rows adjacent to the memory rows that had excessive activation counts. After the victim rows are refreshed, the immediate RowHammer risk may be mitigated. Resetting the status value may allow the control circuitry to begin tracking new accumulations of activation counts. The control circuitry may continue to monitor the activation counters for the memory rows. If additional memory rows exceed the row-activation threshold during subsequent operation, the control circuitry may increment the status value again. The control circuitry may also reset or decrement the activation counters for the memory rows that were addressed by the targeted refresh operations. This cyclical process of status value generation, transmission, targeted refresh, and reset may provide continuous RowHammer protection throughout the operation of the memory device.

In some examples, the control circuitry 420 may be further configured to perform, in response to a targeted refresh command, a targeted refresh of victim rows adjacent to a memory row whose activation counter exceeds the row-activation threshold. The control circuitry 420 may receive a targeted refresh command from the memory controller. The targeted refresh command may include a bank address identifying a memory region. The control circuitry 420 may identify which memory row within that memory region has an activation counter exceeding the row-activation threshold. The control circuitry 420 may determine the addresses of the victim rows adjacent to that memory row. The victim rows may be memory rows that are physically adjacent to the memory row with the excessive activation count. The adjacent victim rows may include the memory row immediately above and the memory row immediately below the excessively activated memory row in the memory array. The control circuitry 420 may perform refresh operations on these victim rows.

In some examples, the targeted refresh of victim rows may restore the charge in the memory cells of the victim rows. The refresh operation may counteract any charge leakage or electrical disturbance caused by the repeated activation of the adjacent memory row. The control circuitry 420 may activate each victim row to transfer the stored charge to the sense amplifiers. The sense amplifiers may amplify and restore the charge. When the memory cell is connected to the sense amplifier, the sense amplifier may amplify the stored voltage to a full logic level of approximately 0 volts for logic 0 or approximately 1 volt for logic 1. This amplified voltage may be connected back to the memory cell via the bitline and the activated pass transistors. The restored values may be written back to the memory cells immediately after activation through this connection. The control circuitry 420 may then precharge the victim rows. The precharge operation may disable the wordline activation and may set the bitline voltage back to an intermediate voltage, such as approximately 0.5 volts. The precharge operation may prepare the bank for activating a different row. For PRAC implementations, the precharge command may also trigger incrementing of the activation counter for the row being precharged. This targeted refresh may prevent data corruption that could otherwise result from the rowhammer effect. The rowhammer effect may cause bit flips in victim rows when an adjacent memory row is activated excessively. By refreshing the victim rows proactively based on the activation counters, the control circuitry may provide effective rowhammer protection. Each targeted refresh command may address the victim rows for one memory row that exceeded the row-activation threshold. Multiple targeted refresh commands may be executed to address multiple memory rows with excessive activation counts in a memory region.

The above described memory device 400 may enable effective RowHammer mitigation by providing per-region status information to the memory controller without requiring the memory controller to maintain activation counters, thereby eliminating area overhead at the memory controller that would otherwise scale with increasing memory capacity. The memory device 400 may omit transmission of a RowHammer-alert signal to the memory controller, thereby eliminating the need for exception handling routines that can disrupt normal memory operations and impact system performance. The memory device 400 may perform transmission of the status value without increasing command bandwidth relative to standard refresh operation because the status value may be transmitted via data lines during time periods when the data lines would otherwise be unused during refresh operations. The memory device 400 may provide fine-grained status information at frequent refresh intervals, enabling timely detection of activation threshold violations. The per-row activation counters maintained by the memory device may provide accurate tracking of RowHammer risk, including accounting for extended open-row durations that contribute to electrical disturbance of adjacent victim rows. The status value transmission in response to refresh commands with the indicator may enable proactive RowHammer protection without requiring additional dedicated commands or modifications to command scheduling.

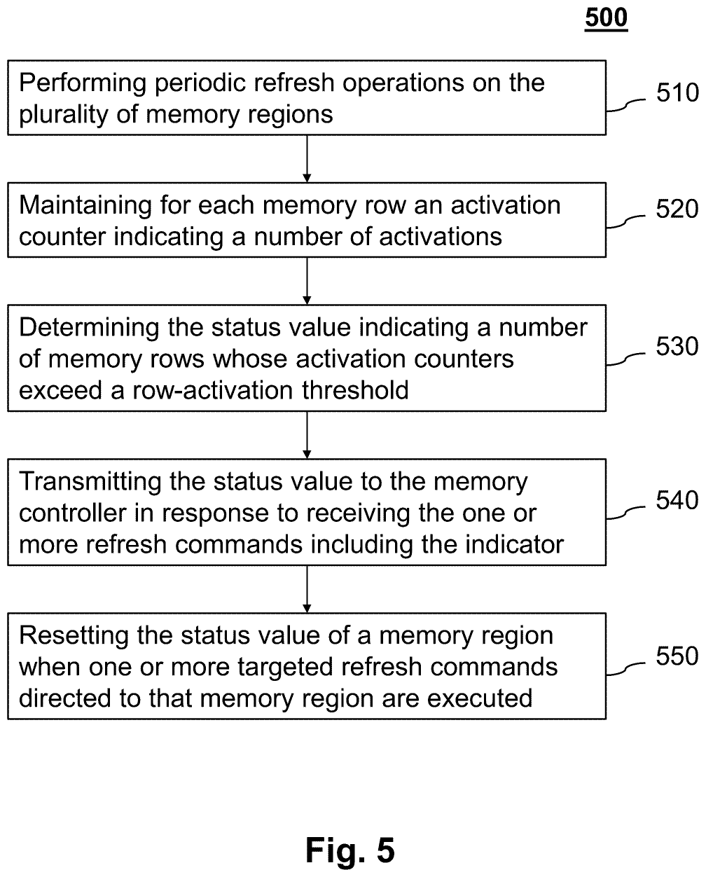

Further details and aspects are mentioned in connection with the examples described above or below. The example shown in FIG. 4 may include one or more optional additional features corresponding to one or more aspects mentioned in connection with the proposed concept or one or more examples described above (e.g., FIGS. 1-3) or below (e.g., FIGS. 5-11).

FIG. 5 illustrates a flowchart of an example of a method 500. The method 500 may, for instance, be performed by an apparatus as described herein, such as memory device 400. The method 500 comprises performing 510 periodic refresh operations on the plurality of memory regions in response to refresh commands received from a memory controller, wherein one or more of the refresh commands include an indicator requesting a status value. The method 500 further comprises maintaining 520, for each memory row within each memory region, an activation counter indicating a number of activations of that memory row. The method 500 further comprises determining 530, for each memory region, the status value indicating a number of memory rows whose activation counters exceed a row-activation threshold. The method 500 further comprises transmitting 540 the status value to the memory controller in response to receiving the one or more refresh commands including the indicator. The method 500 further comprises resetting 550 the status value of a memory region when one or more targeted refresh commands directed to that memory region are executed.

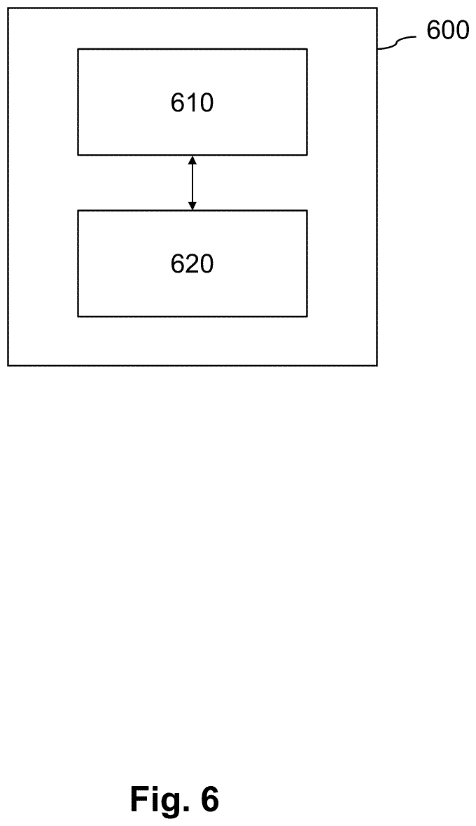

Further details and aspects are mentioned in connection with the examples described above or below. The example shown in FIG. 5 may include one or more optional additional features corresponding to one or more aspects mentioned in connection with the proposed concept or one or more examples described above (e.g., FIGS. 1-4) or below (e.g., FIGS. 6-11).

In some examples, as previously described, the Bank Activation Threshold (BAT) approach may be needed to issue Refresh Management (RFM) commands to minimize the probability of Per Row Activation Counting (PRAC) ALERTs. RFM commands may not be avoided because row activation counts may be monotonically increasing during normal memory operations. As mentioned above, ALERTs may impact performance by triggering exception handling. ALERTs may be quite frequent, especially during a RowHammer attack. The BAT counters may burden the SoC with area overhead that is not scalable as the Dual In-line Memory Module (DIMM) capacity increases. The performance penalty may be based on DDR5 operational characteristics. At full bandwidth, every 3.9 microseconds, there may be 75 activations per bank. The BAT value of 75 may be reached in 1.25 refresh cycles on average. This may result in 350 nanoseconds every 3.9 microseconds multiplied by 1.25, corresponding to a 7.2% reduction in bandwidth for a single-rank DIMM.

In some examples, the disclosed approach may use periodic polling using refresh commands approximately every 3.9 microseconds, as described above with respect to the periodic refresh commands. A bit may be added to the refresh command to optionally enable reading Bank PRAC Status (BPS) as a read data packet. This bit may correspond to the indicator requesting the status value as described above. The 64-bit read data packet may include a 2-bit BPS for each of the 32 banks, consistent with the multi-bit field description provided above (see Table 1).

TABLE 1

| 2-bit Bank | Number of Rows with Per Row | |
|---|---|---|
| PRAC | Activate Counts that Exceed | Number of RFMpb |
| Status | Row Activate Threshold (RAT) | Commands to Issue |
| 00 | 0 | 0 |
| 01 | 1 | 1 |
| 10 | 2 | 2 |
| 11 | 3+ | 4 |

Table 1 shows the encoding of the Bank PRAC Status (BPS) two-bit field and how it maps to the number of RFMpb commands that should be issued. The DRAM device may set the BPS based on the number of rows that exceed the Row Activation Threshold (RAT) in a bank, as previously explained in connection with the status value determination. The memory controller may issue one or more Refresh Management per bank (RFMpb) commands based on the BPS. When the DRAM device receives an RFM command for a bank, the DRAM device may clear the BPS to 00 for that bank, corresponding to the reset operation described above. The DRAM device may increment the BPS again if a row activation count exceeds RAT during precharge. The PRAC ALERT feature may be removed, consistent with the approach of omitting transmission of RowHammer-alert signals as described above.

In some examples, a polling interval of 3.9 microseconds may be sufficient to mitigate RowHammer attacks. The activate rates per refresh period may be considered. The maximum may be 75 activations per refresh period. The maximum number of activations per refresh period may be calculated as 3 times the Refresh Interval (REFI) value, resulting in 225 activations. This maximum may happen at most twice in a row. DRAM cells may be vulnerable to RowHammer when a row reaches 1000 activations. The RAT, as mentioned above, may be set to 661 activations, calculated as 1000 minus 225 times 1.5 minus 1, equaling 661.5. An example worst-case wave attack scenario may be analyzed. Rows may be initialized to 661 activations in every row. The memory controller may issue 225 activations across 5 rows, increasing counts from 661 to 662, 662, 662, 772, 772. The memory controller may issue a Refresh All Banks (REFab) command and read the BPS, utilizing the periodic refresh command with indicator as described above. The memory controller may issue 4 RFMpb commands, corresponding to the targeted refresh commands described above, and one row could have 772 activations. The memory controller may issue 225 activations on one row, increasing the count from 772 to 997. The memory controller may issue a REFab command and read the BPS. The memory controller may issue one RFMpb command, and there may be no more rows with counts that exceed 661.

In some examples, considerations for rows that are kept open (RowPress) may be relevant. The current BAT proposal may suggest counting multiple activations if the row is activated for a longer period of time. Per-row activation counting on the DRAM device may not count a row that is open for a long time as multiple activations when counting the RAT value. The activate-to-precharge time may have a maximum value of 225 nanoseconds, which may be approximately equivalent to 3 activations. A combined RowHammer and RowPress attack with rows kept open for 225 nanoseconds may achieve approximately 334 activations, calculated as 1000 divided by 3. As described above in connection with incrementing activation counters based on open-row duration, the DRAM device may add 1, 2, or 3 to the PRAC counters depending on how long the row has been activated, where the predetermined time threshold may be approximately 225 nanoseconds or subdivisions thereof.

In some examples, other considerations may include maximum bandwidth reduction during a RowHammer attack. One RFMpb command every 661 activations may result in about 0.8% bandwidth reduction. There may be no controller-level Error Correction Code (ECC) protection. The memory controller may need special handling for the data packet's ECC status, similar to Mode Register Read (MRR) commands, but the memory controller may use the same link protection. Multiple DRAM dies in the subchannel may provide redundant copies of similar information, so the memory controller may take the highest BPS for each bank address across different DRAM dies. The refresh command with BPS may introduce a preference for read major mode. DQ bus turnaround time may mean there is a latency penalty when switching between reads and writes. If 4 Refresh Same Bank (REFsb) commands are issued per tREFI (3.9 microseconds), the memory controller may enable BPS only when the memory device is in read major mode, consistent with the selective status value transmission described above. There may be a timeout per rank to force BPS to be read. As described above in connection with enabling NTODT, refresh commands may need Non-Target On-Die Termination (NTODT), like read commands.

In some examples, advantages compared to waiting for ALERT_n may include that no special ALERT_n handling is needed to distinguish between PRAC and Command/Address (CA) parity error and Write Cyclic Redundancy Check (CRC) Error. The approach may not stop traffic and may not block all ranks on two subchannels. The approach may enable using RFMpb which may be more efficient than Refresh Management all banks (RFMab) in terms of timing and number of banks refreshed, as specified in the LPDDR6 standard. These advantages may be consistent with the benefits of omitting RowHammer-alert signal processing as described above. Advantages compared to BAT may include no area overhead for SOC counters and no fixed 7.2% bandwidth reduction for single-rank DIMM, corresponding to the advantage of not maintaining activation counters at the memory controller as previously described. Advantages compared to using mode register reads may include that the memory controller may not need to schedule extra commands like MRR. The latency may be similar to reads, so it may be easy to schedule if there are reads from different banks. Advantages compared to adding a special bit indication in a read data packet during normal reads may include that the approach may work for different metadata and link protection configurations and packet sizes, and may work in 100% write workloads. Advantages compared to polling every 128 milliseconds when the temperature may be polled may include that polling every 3.9 microseconds may be more frequent, resulting in more timely RowHammer mitigation, consistent with the refresh intervals below microseconds described above.

Example of Resetting a Row Activate Count with a Refresh Command

In some examples, a challenge with Per Row Activation Counting (PRAC) may be that row activation counts monotonically increase until a Refresh Management (RFM) command is issued, except when refresh (REF) commands are opportunistically converted to RFM commands. Monotonically increasing may mean that the counts only go up and never decrease during normal operation. Refresh Management per bank (RFMpb) commands may incur 350 nanoseconds of latency, which may temporarily block access to the bank being refreshed. If every row in a bank is activated evenly, RFM commands may not be immediately needed because no individual row exceeds the activation threshold. However, the counters may still increment with each activation, and eventually RFM commands may be required even though no RowHammer threat exists. This behavior may enable a long setup time for a RowHammer attack, allowing an attacker to prepare system state before launching the actual attack. For example, RFM commands may be configured to only refresh rows that have activation counts exceeding 100. An attacker may activate every row in a bank evenly from 0 to 99 activation counts, bringing all rows just below the threshold. The attacker may then activate one target row to increase its count to 100, triggering RFM protection. Every subsequent RFM command may refresh neighboring victim rows adjacent to rows exceeding the threshold. The refresh operation may bring the victim rows' activation counts to 100 as well, causing them to also exceed the threshold. If there are 32,768 rows per bank, this scenario may result in 32,768 RFM commands being issued sequentially, consuming significant bandwidth and time. This cascading effect may create security vulnerabilities and may degrade system performance. The monotonic increase of activation counts without reset mechanisms may allow extended attack preparation periods.

In some examples, an opportunity may exist to reset the row activation counts during sequential refresh cycles. Resetting the activation counts may limit the setup time for a RowHammer attack by preventing counters from accumulating indefinitely through normal distributed access patterns. Before resetting the count for an aggressor row, the neighboring victim rows may need to be refreshed first. The aggressor row may be a row whose activation counter is being considered for reset. The victim rows may include rows at offsets +1, −1, +2, and −2 relative to the aggressor row, meaning the rows immediately above, immediately below, two rows above, and two rows below the aggressor row. After refreshing the neighboring victim rows, the aggressor row may still have time to receive additional activations within three times the refresh interval (3×tREFI), where tREFI is the time between successive refresh commands. Therefore, it may not be appropriate to reset the count to 0 immediately at the next refresh command after victim row refresh, because the aggressor row may have been activated again during the victim refresh period. A monitoring mechanism may be needed to determine whether the aggressor row was activated during the victim refresh period before deciding whether to reset its activation counter. If no activation occurred during monitoring, the counter may be safely reset. If activation did occur, the counter may need to be preserved or adjusted rather than reset to zero.

FIG. 6 illustrates a block diagram of an example of a memory device 600. For example, the memory device 600 described with reference to FIG. 6 may incorporate elements, components, and concepts that have been described above with reference to FIGS. 1 to 5. The terminology, definitions, and technical details established in the preceding descriptions may apply equally to the memory device 600 unless explicitly stated otherwise.

For example, the memory device 600 comprises circuitry that is configured to provide the functionality of the memory device 600. The memory device 600 comprises a plurality of memory rows organized within a memory bank 610. The memory device 600 further comprises control circuitry 620. The components of the memory device 600 are defined as component means, which may correspond to, or implemented by, the respective structural components of the memory device 600. For example, the memory device 600 comprises means for processing 620, which may correspond to or be implemented by the control circuitry 620 and optional means for communicating.

In some examples, the control circuitry 620 may be hardware circuitry configured to control operations of the memory device. The control circuitry 620 may comprise digital logic circuits implemented in semiconductor technology. The control circuitry 620 may include finite state machines that manage command execution sequences and timing. The control circuitry 620 may include command decoders that interpret commands received from the memory controller. The control circuitry 620 may include timing generators that produce control signals with precise timing relationships. The control circuitry 620 may include address decoders that route operations to appropriate memory regions. The control circuitry 620 may include counter circuits that track refresh addresses, activation counts, and other operational parameters. The control circuitry 620 may include comparator circuits that evaluate counter values against thresholds. The control circuitry 620 may include multiplexers and data path control logic that route data between different functional blocks. The control circuitry 620 may be hardwired logic that performs predefined operations in response to commands and internal states. The control circuitry 620 may be distributed across different functional blocks of the memory device or may be centralized in a control unit.

The control circuitry 620 is configured to maintain a per-row activation counter for each of the plurality of memory rows. The control circuitry 620 is further configured to execute a periodic refresh sequence on the memory bank. The refresh sequence is non-sequential and comprises, for a designated aggressor row, refreshing one or more victim rows associated with the designated aggressor row prior to refreshing the designated aggressor row. The control circuitry 620 is further configured to monitor for an activation of the designated aggressor row during a monitoring period corresponding to the refresh of its one or more associated victim rows. The control circuitry 620 is further configured to, in response to completing the refresh of the designated aggressor row, and based on determining that no activation of the designated aggressor row occurred during the monitoring period, resetting the per-row activation counter of the designated aggressor row.

In some examples, the control circuitry 620 may be further configured to, when an activation of the designated aggressor row occurs during the monitoring period, store an activation count value of the designated aggressor row when the designated aggressor row is activated for the first time during the monitoring period, and subtract the stored value from the per-row activation counter following completion of the refresh of the designated aggressor row.

In some examples, the control circuitry 620 may be further configured to monitor for the activation by maintaining one or more Boolean flags, wherein a flag is set to indicate an activation of its corresponding designated aggressor row during the monitoring period.

In some examples, the control circuitry 620 may be further configured to set the one or more Boolean flags by receiving an activate command, calculating a difference between a row address in the activate command and a current refresh row address, and updating a specific flag based on the calculated difference.

In some examples, non-sequential refresh sequence may comprise refreshing a first victim row at a first offset from the designated aggressor row, followed by refreshing a second victim row at a second offset from the designated aggressor row, prior to refreshing the designated aggressor row.

In some examples, resetting the per-row activation counter may comprise setting the counter to a value lower than its value prior to the reset.

In some examples, the value to which the per-row activation counter value is set may be less than or equal to thirty-two.

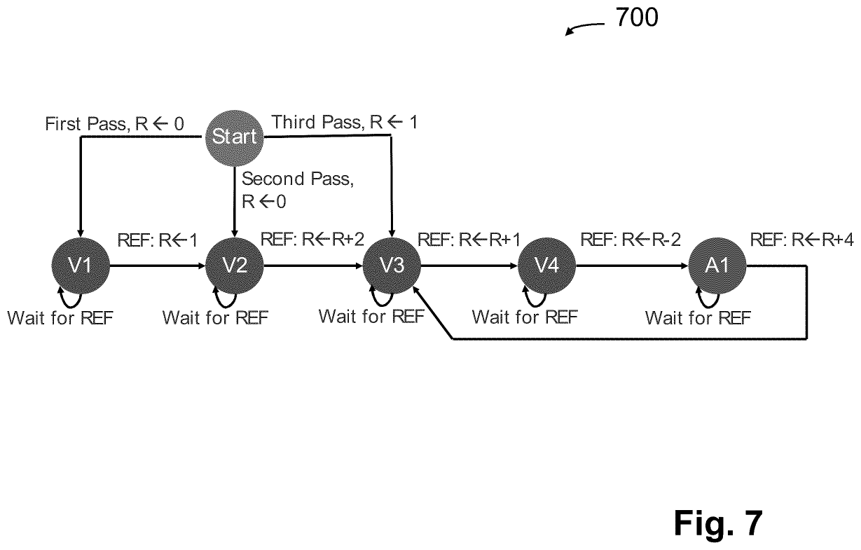

Further details and aspects are mentioned in connection with the examples described above or below. The example shown in FIG. 6 may include one or more optional additional features corresponding to one or more aspects mentioned in connection with the proposed concept or one or more examples described above (e.g., FIGS. 1-5) or below (e.g., FIGS. 7-11).

FIG. 7 illustrates a state machine diagram 700 showing a non-sequential refresh sequence for resetting row activation counts. In some examples, the state machine 700 may be implemented by the control circuitry 620 of the memory device 600 to execute a refresh pattern that refreshes victim rows before refreshing a designated aggressor row. Instead of sequentially incrementing the row addresses during refresh, the refresh sequence may refresh neighboring victim rows followed by a designated aggressor row. This non-sequential pattern may enable monitoring and resetting of activation counters while maintaining RowHammer protection.

In some examples, the refresh sequence may operate in multiple passes through the memory rows. The row order in a first pass may be 0, 1, 3, 4, 2, 6, 7, 5, 9, 10, 8, 12, 13, 11, 15, 16, 14, 18, 19, 17, 21, 22, 20, 24, 25, 23, 27, and so forth. The row order in a second pass may be 1, 2, 0, 4, 5, 3, 7, 8, 6, 10, 11, 9, 13, 14, 12, 16, 17, 15, 19, 20, 18, 22, 23, 21, 25, 26, 24, and so forth. The row order in a third pass may be 0, 2, 3, 1, 5, 6, 4, 8, 9, 7, 11, 12, 10, 14, 15, 13, 17, 18, 16, 20, 21, 19, 23, 24, 22, 26, 27, and so forth. The aggressor rows may be shown in red in the sequence (rows 2, 5, 8, 11, etc. in the first pass). The victim rows may be shown in blue (rows 0, 1, 3, 4 around aggressor row 2). The pattern may ensure that victim rows are refreshed before their corresponding aggressor row.

In some examples, the state machine 700 may comprise multiple states including a Start state, victim refresh states V1, V2, V3, V4, and an aggressor refresh state A1. The state machine 700 may begin at the Start state. From the Start state, the state machine 700 may proceed to state V1 for the first pass when the row address R is set to 0, for the second pass when R is set to 0, or for the third pass when R is set to 1. From state V1, the state machine 700 may wait for a refresh (REF) command. Upon receiving the REF command, the state machine 700 may refresh row R and may transition to state V2 with the next row address set to R+1, meaning one row above the current row.

In some examples, from state V2, the state machine 700 may wait for the next REF command. Upon receiving the REF command, the state machine 700 may refresh row R+2, meaning two rows above the previous row, and may transition to state V3. From state V3, the state machine 700 may wait for the next REF command. Upon receiving the REF command, the state machine 700 may refresh row R-2, meaning two rows below the aggressor row, and may transition to state V4. From state V4, the state machine 700 may wait for the next REF command. Upon receiving the REF command, the state machine 700 may refresh row R+4 and may transition to state A1. At state A1, the state machine 700 may refresh the aggressor row. The aggressor row may be the row whose activation counter is being monitored and potentially reset.

In some examples, the state machine 700 may be implemented as one state machine with different starting points for each pass through the memory rows. The starting point for the first pass may be R set to 0. The starting point for the second pass may be R set to 0. The starting point for the third pass may be R set to 1. The three passes may together ensure that all rows in the bank are eventually designated as aggressor rows and have their activation counters evaluated for reset. The state machine 700 may cycle through states V1, V2, V3, V4, and A1 repeatedly until all rows have been refreshed according to the non-sequential pattern.

In some examples, the control circuitry may track activation activity during the refresh sequence to determine whether the aggressor row has been activated during the last several refresh intervals (tREFI periods). When refreshing the aggressor row, the control circuitry may check if the aggressor row has been activated during the monitoring period. If no activation occurred, the control circuitry may reset the row activation count of the aggressor row to 0 or to some random value or to another low value. The control circuitry may need to maintain Boolean flags to track the recent activation status of aggressor rows. Instead of Boolean flags, the control circuitry may alternatively use counters that can be used to set a limit of extra activations or to add to an initialized count value.

In some examples, the control circuitry may determine activation activity by subtracting the current row to refresh from the row address in an activation command to obtain a difference D. The control circuitry may update flags based on the calculated difference D. At the Start state, the control circuitry may initialize curr_agg_act to 0 and next_agg_act to 0, where curr_agg_act indicates whether there were any recent activations on the current aggressor row and next_agg_act indicates whether there were any recent activations on the next aggressor row. At state V2, if the difference D equals 1, the control circuitry may set curr_agg_act to 1, indicating that the current aggressor row was activated. At state V3, if D equals −1, the control circuitry may set curr_agg_act to 1; otherwise if D equals 2, the control circuitry may set next_agg_act to 1. At state V4, if D equals −2, the control circuitry may set curr_agg_act to 1; otherwise if D equals 1, the control circuitry may set next_agg_act to 1.

In some examples, at state A1, when a REF command is received, the control circuitry may check the curr_agg_act flag. If curr_agg_act equals 0, indicating no recent activation of the current aggressor row, the control circuitry may reset the row activation count for that aggressor row. The control circuitry may then set curr_agg_act equal to next_agg_act, effectively moving the monitoring window forward. The control circuitry may reset next_agg_act to 0 to prepare for monitoring the subsequent aggressor row. If curr_agg_act does not equal 0, indicating that the aggressor row was activated during the monitoring period, the control circuitry may not reset the counter. Instead, if D equals 0, meaning the aggressor row itself is being activated, the control circuitry may set curr_agg_act to 1; otherwise if D equals 3, the control circuitry may set next_agg_act to 1.

In some examples, an illustrative scenario may demonstrate the flag tracking mechanism. The pass number may be the first, second, or third pass. The current row to refresh may be row 15. The state may be V4. The curr_agg_act flag may have a value of 1, indicating that row 13 (the current aggressor row) was recently activated. The next_agg_act flag may have a value of 0, indicating that row 16 (the next aggressor row) has not been recently activated. This tracking mechanism may enable the control circuitry to make informed decisions about whether to reset activation counters based on actual activation activity during the victim row refresh period.

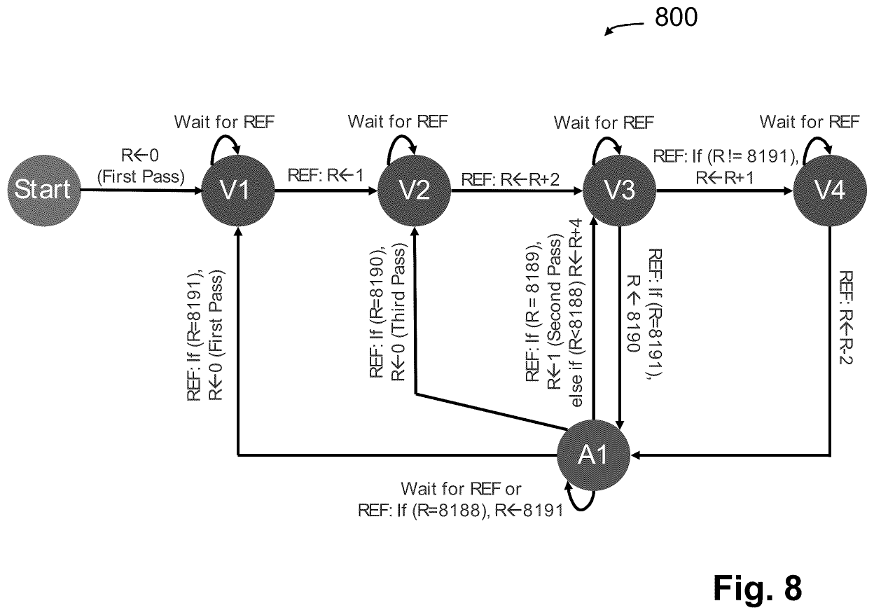

Further details and aspects are mentioned in connection with the examples described above or below. The example shown in FIG. 7 may include one or more optional additional features corresponding to one or more aspects mentioned in connection with the proposed concept or one or more examples described above (e.g., FIGS. 1-6) or below (e.g., FIGS. 8-11).

FIG. 8 illustrates a state machine diagram 800 showing the complete refresh sequence including end-of-bank handling for resetting row activation counts. For example, the state machine 800 may extend the refresh sequence described in FIG. 7 to handle the boundary conditions when the refresh sequence reaches the end of the memory bank. The state machine 800 demonstrates how the non-sequential refresh pattern transitions between passes and wraps around at the bank boundaries.

In some examples, the row order at the end of the first pass may be . . . , 8188, 8186, 8190, 8191, 8189. The row order at the end of the second pass may be . . . , 8188, 8189, 8187, 8191, 8190. The row order at the end of the third pass may be . . . , 8185, 8189, 8190, 8188, 8191. These sequences may ensure that all rows near the end of the bank are properly refreshed with their victim rows before the aggressor rows, even at the bank boundaries.

In some examples, the state machine 800 may comprise the same states as described in FIG. 7: Start, V1, V2, V3, V4, and A1. From the Start state, the state machine 800 may transition to state V1 for the first pass with R set to 0. From state V1, upon receiving a REF command, the state machine 800 may refresh row R and transition to state V2. If the current row R is not equal to 8191, the next row address may be set to R+1. From state V2, upon receiving a REF command, the state machine 800 may refresh row R and transition to state V3 with the next row address set to R+2.

In some examples, from state V3, upon receiving a REF command, the state machine 800 may refresh row R and transition to state V4 with the next row address set to R-2. From state V4, the state machine 800 may have conditional transitions. Upon receiving a REF command in state V3, if the current row R equals 8191, the state machine 800 may refresh row 8191 and transition to state A1, with the next row address set to 8190.

In some examples, from state A1, the state machine 800 may have multiple conditional transitions to handle the end of the refresh sequence. If the current row R equals 8189, upon receiving a REF command, the state machine 800 may refresh row R and transition to state V3 for the second pass with R set to 1. If R equals 8191, the state machine 800 may refresh row R and transition to state V1 for the first pass with R set to 0, beginning a new complete cycle through the bank. If R equals 8190, the state machine 800 may refresh row R and transition to state V2 for the third pass with R set to 0. For other values of R during normal operation, when R equals 8188, the state machine 800 may refresh row R and transition back to state V3 to continue the current pass.

In some examples, the state machine 800 may not need to explicitly store the pass number as a separate variable. The pass number may be fully determined by the combination of the current row address R and the current state. This implementation may reduce the storage requirements for the state machine 800. The state machine 800 may cycle through all three passes automatically based on the row addresses and state transitions, ensuring that every row in the bank eventually serves as a designated aggressor row and has its activation counter evaluated for potential reset.

In some examples, the effectiveness of resetting row activation counts may be evaluated based on the likelihood that counters will be reset during normal operation. If there is no activity in the bank for 96 milliseconds, all row activation counts may be reset. This duration may represent the time required for the refresh sequence to cycle through all rows in the bank multiple times, allowing each row to serve as a designated aggressor row and have its counter evaluated for reset. Even at full bandwidth operation, most of the row activation counts may be reset after 96 milliseconds. The probability that activation counters will be reset may depend on the access patterns and the number of rows involved in the monitoring window.

In some examples, the probability that any of 2 rows are activated in 6 times the refresh interval (6×tREFI) may be calculated. There may be 8192 rows in a portion of the bank being considered, while other rows in the bank are refreshed in parallel. During 6×tREFI, if tREFI is 3.9 microseconds and refresh takes 50 nanoseconds and read or write takes 50 nanoseconds, the maximum number of activations may be 462. The random probability that none of the 462 activations target any of the 6 rows in the monitoring window may be calculated as ((8192-6)/8192) raised to the power of 462, which equals approximately 0.89. This calculation may indicate that there is an 89% probability that the activation counter for an aggressor row will be reset during a single evaluation opportunity. Over multiple refresh cycles, the cumulative probability of reset may approach 100%, ensuring that activation counters do not accumulate indefinitely under normal distributed access patterns. This effectiveness analysis may demonstrate that the non-sequential refresh sequence with counter reset may significantly limit the setup time available for RowHammer attacks while maintaining compatibility with normal memory operations.

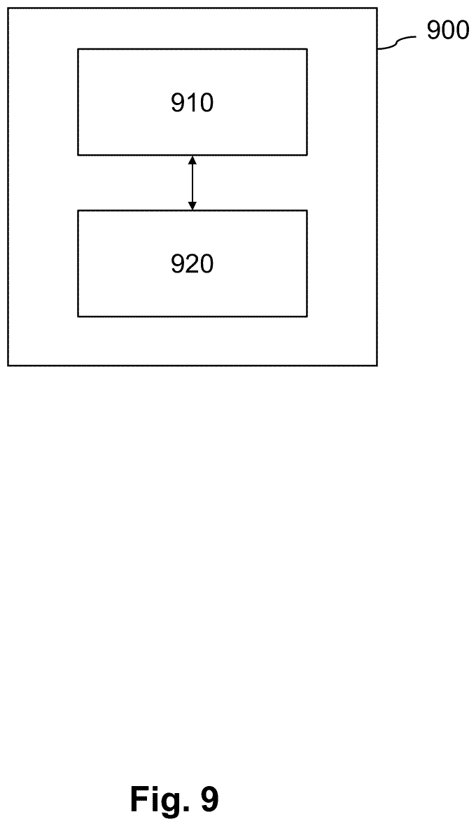

Further details and aspects are mentioned in connection with the examples described above or below. The example shown in FIG. 8 may include one or more optional additional features corresponding to one or more aspects mentioned in connection with the proposed concept or one or more examples described above (e.g., FIGS. 1-7) or below (e.g., FIGS. 9-11).

Example of Memory Device RFM with Four Refreshes Instead of Five

In some examples, Refresh Management (RFM) commands for Per Row Activation Counting (PRAC) may have a relatively long latency. The RFM latency may be calculated as (4+1) times 70 nanoseconds, equaling 350 nanoseconds in Low Power Double Data Rate 6 (LPDDR6). For Double Data Rate 5 (DDR5) PRAC and LPDDR6 PRAC, the RFM command may refresh 4 victim rows and 1 aggressor row, totaling 5 refresh operations. The victim rows may be memory rows physically adjacent to an aggressor row that has been activated excessively. The aggressor row may be a memory row whose activation count has exceeded a threshold, indicating potential RowHammer risk. The aggressor row may not need to be refreshed for data retention purposes because the aggressor row was recently activated and its data is still valid. However, with PRAC, the row activation count for the aggressor row may need to be updated or reset, which may require the row to be activated. Activating and refreshing the aggressor row may add 70 nanoseconds to the RFM command latency, where 70 nanoseconds represents the time required to refresh one row (tRRF). This additional latency may affect bandwidth and idle latency in memory systems.

In some examples, previous RowHammer mitigation solutions may have taken a different approach. Intel's Pseudo Target Row Refresh (pTRR) and Directed Refresh Management (DRFM) may only refresh the victim rows without refreshing the aggressor row. pTRR may be a RowHammer mitigation technique that refreshes neighboring victim rows based on statistical tracking. DRFM may be another RowHammer mitigation approach that directs refresh operations to specific victim rows. These approaches may not maintain a per-row activation count that needs to be updated. A per-row activation count may be a counter that tracks how many times each individual memory row has been activated. Without per-row activation counters, there may be no need to activate the aggressor row during targeted refresh operations. However, PRAC-based approaches may maintain per-row activation counters to enable more precise RowHammer detection and mitigation, creating the need for a mechanism to update or reset these counters.

In some examples, an alternative approach may address the RFM latency issue while maintaining per-row activation counters. During the precharge command when the aggressor row is moved to a service queue awaiting RFM commands, the aggressor row's activation count may be stored in the service queue. A precharge command may be a command that closes an open memory row and prepares the bank for accessing a different row. A service queue may be a data structure or storage area maintained by the control circuitry to track aggressor rows that require targeted refresh operations. The row activation count in the DRAM memory array may be cleared to 0 immediately during the precharge operation, without waiting for the RFM command. Future queries about the row's activation count may check the latest value in the service queue rather than only checking the counter stored in the memory array. This approach may mean that no additional row refresh is needed to clear the row activation count for the aggressor row in the DRAM memory array when the RFM command is issued. The RFM command may only need to refresh the 4 victim rows, omitting the refresh of the aggressor row itself. This may reduce the total latency from (4+1)×tRRF to 4×tRRF, where tRRF is the row refresh latency. This may reduce the time and power needed to perform the RFM command by approximately 20%. The reduced RFM latency may be included in the DDR6 standard or other DRAM standard and in DRAM datasheets as 4×tRRF instead of (4+1)×tRRF. The primary way to take advantage of the reduced latency may be to schedule other commands sooner after the RFM command completes, improving overall memory system performance and reducing idle time.

In some examples, the PRAC RFM command in DDR5 and LPDDR6 may refresh an aggressor row A and its neighbors in rows A+1, A−1, A+2, A−2, for a total of 5 refreshes. Previous approaches such as pTRR and DRFM may only refresh the victim rows and not the aggressor row A. PRAC may require the count of the aggressor row to be reset, which may require a refresh to row A. This requirement may increase the latency of the PRAC RFM command, which may affect bandwidth and idle latency.

FIG. 9 illustrates a block diagram of an example of a memory device 900. For example, the memory device 900 described with reference to FIG. 9 may incorporate elements, components, and concepts that have been described above with reference to FIGS. 1 to 8. The terminology, definitions, and technical details established in the preceding descriptions may apply equally to the memory device 900 unless explicitly stated otherwise.

For example, the memory device 900 comprises circuitry that is configured to provide the functionality of the memory device 900. The memory device 900 comprises a memory array 910 comprising a plurality of memory rows. The memory device 900 further comprises control circuitry 920. The components of the memory device 900 are defined as component means, which may correspond to, or implemented by, the respective structural components of the memory device 900. For example, the memory device 900 comprises means for processing 920, which may correspond to or be implemented by the control circuitry 920 and optional means for communicating.

In some examples, the control circuitry 920 may be hardware circuitry configured to control operations of the memory device. The control circuitry 920 may comprise digital logic circuits implemented in semiconductor technology. The control circuitry 920 may include finite state machines that manage command execution sequences and timing. The control circuitry 920 may include command decoders that interpret commands received from the memory controller. The control circuitry 920 may include timing generators that produce control signals with precise timing relationships. The control circuitry 920 may include address decoders that route operations to appropriate memory regions. The control circuitry 920 may include counter circuits that track refresh addresses, activation counts, and other operational parameters. The control circuitry 920 may include comparator circuits that evaluate counter values against thresholds. The control circuitry 920 may include multiplexers and data path control logic that route data between different functional blocks. The control circuitry 920 may be hardwired logic that performs predefined operations in response to commands and internal states. The control circuitry 920 may be distributed across different functional blocks of the memory device or may be centralized in a control unit.

The control circuitry 920 is configured to maintain a per-row activation counter for each of the plurality of memory rows within the memory array. The control circuitry 920 is further configured to, in response to detecting that a per-row activation counter for a designated aggressor row has reached a threshold: Store an identifier of the designated aggressor row and its corresponding counter value in a service queue, and reset the per-row activation counter for the designated aggressor row in the memory array. The control circuitry 920 is further configured to, in response to subsequently receiving a targeted refresh command associated with the designated aggressor row: Perform one or more refresh operations on one or more victim rows associated with the designated aggressor row, and omit performing a refresh operation on the designated aggressor row.

In some examples, the control circuitry 920 may be further configured to detect that the threshold has been reached during a precharge command for the designated aggressor row.

In some examples, resetting the per-row activation counter in the memory array may comprise setting the counter to a value lower than its value prior to the reset.

In some examples, the value to which the per-row activation counter value is set may be less than or equal to thirty-two.

In some examples, the service queue may be configured to store, for each entry, both the row identifier and the corresponding counter value.

In some examples, the control circuitry may add the activation count C to a service queue to avoid refreshing row A. When a precharge command results in a RowHammer aggressor row A reaching a threshold, the control circuitry may follow a specific procedure. If row A is not in the service queue and the service queue is not full, the control circuitry may store row address A and an incremented row activation count C in the service queue. The control circuitry may write 0 for the row activation count for row A in the memory array. If the incremented count C reaches back off threshold, the control circuitry may trigger an ALERT signal. If the service queue is full, the control circuitry may increment the row activation count in the memory array. If the row activation count for row A in the memory array reaches back off threshold, the control circuitry may trigger ALERT. If rowA is already in the service queue, the control circuitry may increment C. The control circuitry may write 0 for the row activation count for row A in the memory array. If C reaches back off threshold, the control circuitry may trigger ALERT.

In some examples, when an RFM command is issued by the memory controller, the control circuitry may need to refresh the RowHammer victim rows A+1, A−1, A+2, A−2 of aggressor row A. The control circuitry may refresh the four victim rows A+1, A−1, A+2, A−2. The control circuitry may remove A from the service queue, for example by setting a Valid bit V to 0 for that entry. This approach may eliminate the need to refresh row A itself during the RFM command, reducing the number of refresh operations from 5 to 4.

In some examples, the implementation may involve trade-offs related to additional logic requirements. The control circuitry may need to add a 16-bit counter C per row in the service queue. This addition may double the size of the service queue. A service queue for a bank may comprise multiple entries, where each entry includes a RowHammer aggressor row address field (17 bits in this example), a row activation count field C (16 bits), and a Valid bit V (1 bit). For example, the service queue may include an entry with row address 17900 (in decimal), row activation count 300, and Valid bit 1. Another entry may have row address 345, row activation count 400, and Valid bit 1. Another entry may have row address 6023, row activation count 500, and Valid bit 1. Another entry may have row address 5038, row activation count 600, and Valid bit 0, indicating an invalid or unused entry.

In some examples, the performance impact may be evaluated. RFM commands may be rare in typical operation. In a worst case scenario, one RFM command may be issued every 256 activates if the Bank Activation Threshold is 256. Saving up to 1 activation for every 256 activates may result in a 0.39% reduction in power and improvement in bandwidth. In situations where there is a burst of RFM commands, the commands may finish faster due to the reduced latency. The latency impact may also affect quality of service (QoS) for idle latency, as memory accesses may be able to proceed sooner after RFM commands complete.

In some examples, a detailed operational scenario may illustrate the mechanism as illustrated in table 2 below. At time step 1, an Activate Row 1000 command may be received. The Rowhammer Aggressor Row A field may contain X indicating no entry. The Row activation count C field may contain X. The Valid V bit may be 0. The Row Activation count for Row 1000 in the memory array may be 255. At time step 2, a Precharge Row 1000 command may be received. The Rowhammer Aggressor Row A field may contain 1000 (the row that just reached threshold). The Row activation count C field may contain 256 (the count at threshold). The Valid V bit may be 1. The Row Activation count for Row 1000 in the memory array may be 0 (reset during precharge). At time step 3, an Activate Row 1000 command may be received. Row A may still be 1000. Count C may still be 256. Valid V may be 1. The Row Activation count for Row 1000 in the memory array may be 0 (still reset, as the count is being tracked in the service queue). At time step 4, a Precharge Row 1000 command may be received. Row A may still be 1000. Count C may be 257 (incremented in the service queue). Valid V may be 1. The Row Activation count for Row 1000 in the memory array may remain 0. At time step 5, an RFM command may be issued. After the RFM command, Row A may contain X (entry removed). Count C may contain X. Valid V may be 0 (entry invalidated). The Row Activation count for Row 1000 in the memory array may remain 0. At time step 6, an Activate Row 1000 command may be received. Row A may contain X. Count C may contain X. Valid V may be 0. The Row Activation count for Row 1000 in the memory array may remain 0. At time step 7, a Precharge Row 1000 command may be received. Row A may contain X. Count C may contain X. Valid V may be 0. The Row Activation count for Row 1000 in the memory array may be 1 (normal counting resumes). At time step 8, an Activate Row 1000 command may be received. Row A may contain X. Count C may contain X. Valid V may be 0. The Row Activation count for Row 1000 in the memory array may be 1. At time step 9, a Precharge Row 1000 command may be received. Row A may contain X. Count C may contain X. Valid V may be 0. The Row Activation count for Row 1000 in the memory array may be 2. This example may demonstrate how the service queue mechanism allows the activation counter to be reset immediately in the memory array while maintaining the actual count in the service queue until the RFM command is executed.

TABLE 2

| | | Rowhammer | Row | | Row Activation |
|---|---|---|---|---|---|
| | | Aggressor | activation | Valid, | count for Row |
| Time | | Row, A | count, C | V (1 | 1000 in memory |
| Step | Command | (17 bits) | (16 bits) | bit) | array (16 bits) |
| 1 | Activate | X | X | 0 | 255 |
| | Row 1000 | | | | |
| 2 | Precharge | 1000 | 256 | 1 | 0 |
| | Row 1000 | | | | |
| 3 | Activate | 1000 | 256 | 1 | 0 |
| | Row 1000 | | | | |
| 4 | Precharge | 1000 | 257 | 1 | 0 |
| | Row 1000 | | | | |
| 5 | RFM | X | X | 0 | 0 |
| 6 | Activate | X | X | 0 | 0 |
| | Row 1000 | | | | |
| 7 | Precharge | X | X | 0 | 1 |
| | Row 1000 | | | | |
| 8 | Activate | X | X | 0 | 1 |
| | Row 1000 | | | | |
| 9 | Precharge | X | X | 0 | 2 |
| | Row 1000 | | | | |

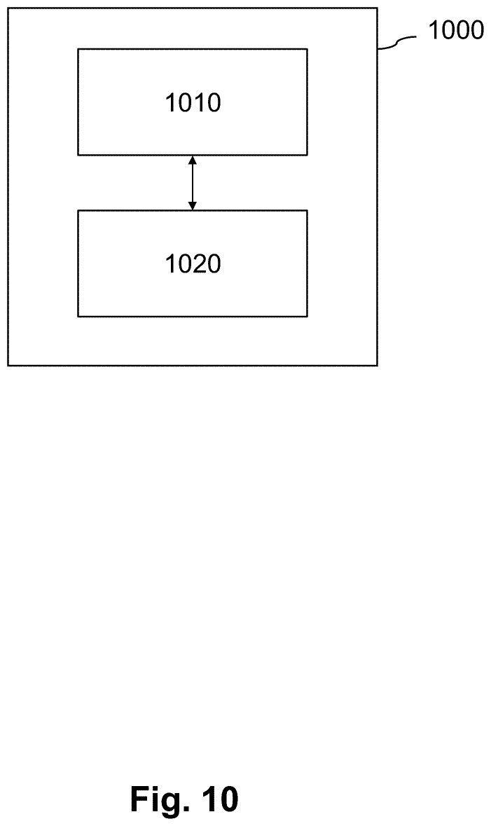

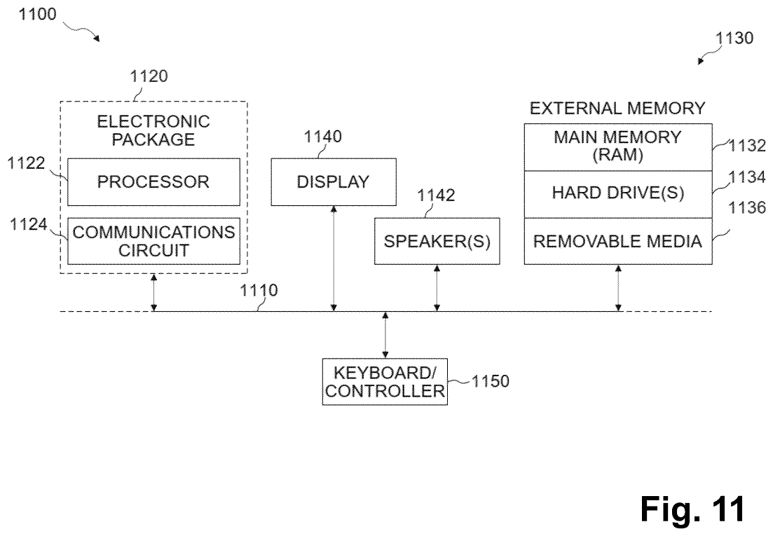

Further details and aspects are mentioned in connection with the examples described above or below. The example shown in FIG. 9 may include one or more optional additional features corresponding to one or more aspects mentioned in connection with the proposed concept or one or more examples described above (e.g., FIGS. 1-8) or below (e.g., FIGS. 10-11).

### Example of Memory Device Stealing Multiple REF Commands for RFM

In some examples, a challenge may exist with opportunistically converting refresh commands to RFM commands in certain memory standards. To mitigate RowHammer attacks with PRAC, refresh (REF) commands may be stolen and converted into RFM commands. Stealing may mean intercepting or repurposing refresh commands that would normally refresh sequential rows and instead using them to perform targeted refresh operations on victim rows. The term “opportunistically” may mean that the DRAM device internally decides to perform RFM operations instead of normal refresh operations when RowHammer conditions are detected, without requiring explicit RFM commands from the memory controller.

In some examples, Low Power Double Data Rate 6 (LPDDR6) refresh cycle time for refresh per bank (tRFCdb) may be too short for the DRAM device to handle Refresh per bank (REFdb) commands as RFMpb commands. DDR5 PRAC may have allowed the DRAM device to handle REF commands as RFM internally when needed, meaning the DRAM device could complete a full RFM operation within the time allocated for a single REF command. However, LPDDR6 tRFCdb may be 140 nanoseconds to 210 nanoseconds, depending on DRAM density. The tRFCdb parameter may specify the minimum time interval between the start of one REFdb command and the start of the next command to the same bank. This interval may need to accommodate the completion of all internal refresh operations. An RFMpb command in LPDDR6 may need 70 nanoseconds multiplied by 5, equaling 350 nanoseconds, to complete all five refresh operations. The five refresh operations may comprise refreshing four victim rows (at addresses A+1, A-1, A+2, A−2 relative to aggressor row A) plus refreshing the aggressor row A itself to reset its activation counter. Because 350 nanoseconds exceeds the available tRFCdb window of 140 to 210 nanoseconds, the DRAM device may not be able to opportunistically perform RFMpb commands instead of REFdb commands when needed. The timing constraint may prevent the single-command conversion approach that was feasible in DDR5.

FIG. 10 illustrates a block diagram of an example of a memory device 1000. For example, the memory device 1000 described with reference to FIG. 10 may incorporate elements, components, and concepts that have been described above with reference to FIGS. 1 to 9. The terminology, definitions, and technical details established in the preceding descriptions may apply equally to the memory device 1000 unless explicitly stated otherwise.

For example, the memory device 1000 comprises circuitry that is configured to provide the functionality of the memory device 1000. The memory device 1000 comprises a memory array 1010 comprising a plurality of memory rows. The memory device 1000 further comprises control circuitry 1020. The components of the memory device 1000 are defined as component means, which may correspond to, or implemented by, the respective structural components of the memory device 1000. For example, the memory device 1000 comprises means for processing 1020, which may correspond to or be implemented by the control circuitry 1020 and optional means for communicating.

In some examples, the control circuitry 1020 may be hardware circuitry configured to control operations of the memory device. The control circuitry 1020 may comprise digital logic circuits implemented in semiconductor technology. The control circuitry 1020 may include finite state machines that manage command execution sequences and timing. The control circuitry 1020 may include command decoders that interpret commands received from the memory controller. The control circuitry 1020 may include timing generators that produce control signals with precise timing relationships. The control circuitry 1020 may include address decoders that route operations to appropriate memory regions. The control circuitry 1020 may include counter circuits that track refresh addresses, activation counts, and other operational parameters. The control circuitry 1020 may include comparator circuits that evaluate counter values against thresholds. The control circuitry 1020 may include multiplexers and data path control logic that route data between different functional blocks. The control circuitry 1020 may be hardwired logic that performs predefined operations in response to commands and internal states. The control circuitry 1020 may be distributed across different functional blocks of the memory device or may be centralized in a control unit.

The control circuitry 1020 is further configured is to, in response to detecting that a per-row activation counter for a designated aggressor row has reached a threshold: Store an identifier of the designated aggressor row in the service queue, and associate a mitigation state with the identifier, the mitigation state being initialized to a first state. The control circuitry 1020 is further configured is to, in response to receiving a first periodic refresh command while the identifier is in the service queue and the mitigation state is the first state: Perform a first portion of a targeted refresh operation by refreshing a first subset of victim rows associated with the designated aggressor row, and update the mitigation state in the service queue to a second state. The control circuitry 1020 configured is to, in response to receiving a second periodic refresh command while the identifier is in the service queue and the mitigation state is the second state perform a second portion of the targeted refresh operation by refreshing a second subset of victim rows associated with the designated aggressor row.

In some examples, the control circuitry 1020 is further configured to, in response to detecting the threshold, store a counter value in the service queue and reset the per-row activation counter in the memory array a value lower than its value prior to the reset.

In some examples, the value to which the per-row activation counter value is set is less than or equal to thirty-two.

In some examples, the control circuitry 1020 may be further configured to, in response to an activation of the designated aggressor row while the mitigation state is the second state, increment a counter value stored in the service queue and increment the per-row activation counter in the memory array.

In some examples, the first subset of victim rows may comprise rows at a first offset, and the second subset of victim rows comprises rows at a second offset.

In some examples, the first state may be an awaiting mitigation state and the second state may be a partially complete state. In some examples, there may be further states.

In some examples, an alternative approach may emulate an RFM operation in one or two, or three, or four, or five steps or more steps using multiple refresh commands. When a precharge command results in RowHammer aggressor row A reaching a threshold, the control circuitry may follow a procedure that tracks the multi-step RFM operation. If row A is not in the service queue and the service queue is not full, the control circuitry may store row address A and an incremented row activation count C in the service queue with an RFM state set to PENDING. The PENDING state may indicate that the targeted refresh operation has not yet been initiated. The control circuitry may write 0 for the row activation count for row A in the memory array, resetting the counter immediately. If the count C reaches a back-off threshold, the control circuitry may trigger an ALERT signal. If the service queue is full, the control circuitry may increment the row activation count for row A in the memory array instead. If the row activation count for row A in the memory array reaches the back-off threshold, the control circuitry may trigger ALERT. If row A is already in the service queue and the RFM state is PENDING, the control circuitry may increment the count C stored in the service queue. The control circuitry may write 0 for the row activation count for row A in the memory array. If the RFM state is STEP2, indicating that the first portion of the targeted refresh has been completed, the control circuitry may increment C in the service queue. The control circuitry may also increment the row activation count for row A in the memory array because the second step is in progress. If C reaches the back-off threshold, the control circuitry may trigger ALERT.

In some examples, the control circuitry may use the time allocated for two REFdb commands to emulate one RFMpb command. The control circuitry may need to refresh victim rows at addresses A+1, A−1, A+2, A−2 relative to aggressor row A. If the RFM state in the service queue is PENDING, the control circuitry may, in response to receiving a first periodic refresh command, perform a first portion of the targeted refresh operation. The control circuitry may refresh the first subset of victim rows, specifically rows A+1 and A−1. These rows may be the victim rows immediately adjacent to aggressor row A. The control circuitry may change the RFM state to STEP2, indicating that the first half of the victim row refresh is complete. If the RFM state is STEP2, the control circuitry may, in response to receiving a second periodic refresh command, perform a second portion of the targeted refresh operation. The control circuitry may refresh the second subset of victim rows, specifically rows A+2 and A-2. These rows may be the victim rows at a distance of two rows from aggressor row A. The control circuitry may then remove row A from the service queue, for example by setting a Valid bit V to 0 for that entry. This two-step approach may allow the RFM operation to fit within the tRFCdb timing constraints of LPDDR6 by splitting the four victim row refreshes across two separate REFdb commands.

In some examples, considerations for timely RFM commands may be addressed. The DRAM device may internally issue RFM commands to rows with high activation counts within one tREFI period, which may be approximately 3.906 microseconds. This timing may ensure that RowHammer mitigation occurs promptly before excessive activations can cause data corruption.

In some examples, considerations for missed refresh cycles may be relevant. If the control circuitry steals two refreshes for every 256 activates, with 64 activates per bank per tREFI for two banks, the control circuitry may use up to 4 out of 4 REFdb commands, corresponding to 100% utilization. The rate may be much lower if activates are spread across many rows in the bank rather than concentrated on a few rows. The rate may also be lower if the control circuitry periodically clears PRAC counts. For example, the Panopticon paper may suggest clearing the lower 5 bits of activation counters during normal refresh commands. The control circuitry may catch up on missed refresh commands by periodically polling. This approach may allow polling less frequently, for example every 16 tREFI intervals, reducing overhead while maintaining data integrity. In some examples, additional logic requirements may involve trade-offs. The control circuitry may need to add a 16-bit counter C and a 1-bit RFM state field per row in the service queue. This addition may double the size of the service queue compared to implementations that only store row addresses. The control circuitry may limit only one row to STEP2 state to reduce the number of RFM State bits required.

A service queue for a bank may comprise multiple entries with different states as illustrated in table 3. For example, the service queue may include an entry with Rowhammer Aggressor Row address 17900 (17 bits), Row activation count 300 (16 bits), RFM State PENDING (1 bit), and Valid bit 1. Another entry may have row address 345, count 400, RFM State STEP2, and Valid bit 1. Another entry may have row address 6023, count 500, RFM State PENDING, and Valid bit 1. Another entry may have row address 5038, count 600, RFM State PENDING, and Valid bit 0 indicating an invalid or unused entry.

TABLE 3

| Rowhammer Aggressor | Row activation | RFM State | Valid, V |
|---|---|---|---|
| Row, A (17 bits) | count, C (16 bits) | (1 bits) | (1 bit) |
| 17900 | 300 | PENDING | 1 |
| 345 | 400 | STEP2 | 1 |
| 6023 | 500 | PENDING | 1 |
| 5038 | 600 | PENDING | 0 |

In some examples, a detailed operational scenario may illustrate the two-step RFM emulation mechanism as illustrated in table 4. At time step 1, an Activate Row 1000 command may be received. The Rowhammer Aggressor Row A field may contain X indicating no entry. The Row activation count C field may contain X. The RFM State field may contain X. The Valid V bit may be 0. The Row Activation count for Row 1000 in the memory array may be 255. At time step 2, a Precharge Row 1000 command may be received. The Rowhammer Aggressor RowA field may contain 1000, indicating the row that just reached the threshold. The Row activation count C field may contain 256, the count at the threshold. The RFM State may be PENDING, indicating that targeted refresh has not yet started. The Valid V bit may be 1. The Row Activation count for Row 1000 in the memory array may be 0, reset during precharge. At time step 3, an Activate Row 1000 command may be received. Row A may still be 1000. Count C may still be 256. RFM State may still be PENDING. Valid V may be 1. The Row Activation count for Row 1000 in the memory array may be 0, still reset because the count is being tracked in the service queue. At time step 4, a Precharge Row 1000 command may be received. Row A may still be 1000. Count C may be 257, incremented in the service queue. RFM State may still be PENDING. Valid V may be 1. The Row Activation count for Row 1000 in the memory array may remain 0. At time step 5, a first REFdb command may be issued. The control circuitry may refresh victim rows A+1 and A-1. Row A may still be 1000. Count C may still be 257. RFM State may change to STEP2, indicating that the first portion of targeted refresh is complete. Valid V may be 1. The Row Activation count for Row 1000 in the memory array may remain 0. At time step 6, an Activate Row 1000 command may be received. Row A may still be 1000. Count C may still be 257. RFM State may be STEP2. Valid V may be 1. The Row Activation count for Row 1000 in the memory array may remain 0. At time step 7, a Precharge Row 1000 command may be received. Row A may still be 1000. Count C may be 258, incremented in the service queue. RFM State may still be STEP2. Valid V may be 1. The Row Activation count for Row 1000 in the memory array may be 1, incremented because the RFM state is STEP2. At time step 8, an Activate Row 1000 command may be received. Row A may still be 1000. Count C may still be 258. RFM State may still be STEP2. Valid V may be 1. The Row Activation count for Row 1000 in the memory array may be 1. At time step 9, a Precharge Row 1000 command may be received. Row A may still be 1000. Count C may be 259. RFM State may still be STEP2. Valid V may be 1. The Row Activation count for Row 1000 in the memory array may be 2. At the second time step 5, a second REFdb command may be issued. The control circuitry may refresh victim rows A+2 and A-2, completing the targeted refresh operation. After this REFdb command, Row A may contain X, indicating the entry has been removed. Count C may contain X. RFM State may contain X. Valid V may be 0, indicating the entry is no longer valid. The Row Activation count for Row 1000 in the memory array may be 2. At subsequent time steps 6 through 9, normal activation and precharge operations may occur. The Row Activation count for Row 1000 in the memory array may increment normally to 2, 3, 3, and 4 respectively, as normal counting resumes after the RFM operation completes.

TABLE 4

| | | | | | | Row |
|---|---|---|---|---|---|---|
| | | | | | | Activation |
| | | Rowhammer | Row | | | count for |
| | | Aggressor | activation | RFM | Valid, | Row 1000 in |
| Time | | Row, A | count, C | State | V | memory array |
| Step | Command | (17 bits) | (16 bits) | (1 bit) | (1 bit) | (16 bits) |
| 1 | Activate | X | X | X | 0 | 255 |
| | Row 1000 | | | | | |
| 2 | Precharge | 1000 | 256 | PENDING | 1 | 0 |
| | Row 1000 | | | | | |
| 3 | Activate | 1000 | 256 | PENDING | 1 | 0 |
| | Row 1000 | | | | | |
| 4 | Precharge | 1000 | 257 | PENDING | 1 | 0 |
| | Row 1000 | | | | | |
| 5 | REFdb | 1000 | 257 | STEP2 | 1 | 0 |
| 6 | Activate | 1000 | 257 | STEP2 | 1 | 0 |
| | Row 1000 | | | | | |
| 7 | Precharge | 1000 | 258 | STEP2 | 1 | 1 |
| | Row 1000 | | | | | |
| 8 | Activate | 1000 | 258 | STEP2 | 1 | 1 |
| | Row 1000 | | | | | |
| 9 | Precharge | 1000 | 259 | STEP2 | 1 | 2 |
| | Row 1000 | | | | | |
| 5 | REFdb | X | X | X | 0 | 2 |
| 6 | Activate | X | X | X | 0 | 2 |
| | Row 1000 | | | | | |
| 7 | Precharge | X | X | X | 0 | 3 |
| | Row 1000 | | | | | |
| 8 | Activate | X | X | X | 0 | 3 |
| | Row 1000 | | | | | |
| 9 | Precharge | X | X | X | 0 | 4 |
| | Row 1000 | | | | | |

Further details and aspects are mentioned in connection with the examples described above or below. The example shown in FIG. 10 may include one or more optional additional features corresponding to one or more aspects mentioned in connection with the proposed concept or one or more examples described above (e.g., FIGS. 1-9) or below (e.g., FIG. 11).

FIG. 11 illustrates an example of a block diagram of an electronic apparatus 1100 incorporating at least one electronic assembly 100, 200, 400, 600, 900, 1000 and/or methods 300, 500 described herein. Electronic apparatus 1100 is merely one example of an electronic apparatus in which forms of the electronic assemblies 100, 200, 400, 600, 900, 1000 and/or methods 300, 500 described herein may be used. Examples of an electronic apparatus 1100 include, but are not limited to, personal computers, tablet computers, mobile telephones, game devices, MP3 or other digital music players, etc. In this example, electronic apparatus 1100 comprises a data processing system that includes a system bus 1110 to couple the various components of the electronic apparatus 1100. System bus 1110 provides communications links among the various components of the electronic apparatus 1100 and may be implemented as a single bus, as a combination of busses, or in any other suitable manner.

An electronic assembly 1120 as describe herein may be coupled to system bus 1110. The electronic assembly 1120 may include any circuit or combination of circuits. In one embodiment, the electronic assembly 1120 includes a processor 1122 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that may be included in electronic assembly 1120 are a custom circuit, an application-specific integrated circuit (ASIC), or the like, such as, for example, one or more circuits (such as a communications circuit 1124) for use in wireless devices like mobile telephones, tablet computers, laptop computers, two-way radios, and similar electronic systems. The IC can perform any other type of function.

The electronic apparatus 1100 may also include an external memory 1130, which in turn may include one or more memory elements suitable to the particular application, such as a main memory 1132 in the form of random access memory (RAM), one or more hard drives 1134, and/or one or more drives that handle removable media 1136 such as compact disks (CD), flash memory cards, digital video disk (DVD), and the like.

The electronic apparatus 1100 may also include a display device 1140, one or more speakers 1142, and a keyboard and/or controller 1150, which can include a mouse, trackball, touch screen, voice-recognition device, or any other device that permits a system user to input information into and receive information from the electronic apparatus 1100.

Further details and aspects are mentioned in connection with the examples described above. The example shown in FIG. 11 may include one or more optional additional features corresponding to one or more aspects mentioned in connection with the proposed concept or one or more examples described above (e.g., FIGS. 1-10).

In the following, some examples of the proposed technique are presented:

An example (e.g., example 1) relates to a non-transitory computer-readable medium storing instructions that, when executed by one or more processing circuitries, cause the one or more processing circuitries to perform a method comprising issuing periodic refresh commands to a memory device configured to perform refresh operations on a plurality of its memory regions, each memory region being a portion of the memory device comprising a plurality of memory rows, wherein at least one of the periodic refresh commands includes an indicator requesting a status value, receiving, in response to the periodic refresh command including the indicator, the status value transmitted from the memory device, the status value indicating, for each memory region, a number of memory rows whose activation counts exceed a row-activation threshold, determining based on the status value whether a targeted-refresh condition is satisfied for one or more of the memory regions, and in response to determining that the targeted-refresh condition is satisfied for one or more memory regions, transmitting, for each of the one or more memory regions, a number of targeted refresh commands to the memory device, the number being based on the status value of the corresponding memory region.

Another example (e.g., example 2) relates to a previous example (e.g., example 1) or to any other example, further comprising that the status value comprises, for each memory region, a multi-bit field representing a number of memory rows whose activation counts exceed the row-activation threshold.

Another example (e.g., example 3) relates to a previous example (e.g., example 2) or to any other example, further comprising that the multi-bit field comprises a two-bit field representing whether none, one, two, or three or more memory rows have activation counts exceeding the row-activation threshold.

Another example (e.g., example 4) relates to a previous example (e.g., one of the examples 1 to 3) or to any other example, further comprising that determining that the targeted-refresh condition is satisfied comprises identifying, based on the status value of each memory region, a number of targeted refresh commands to transmit to the memory device, the number being proportional to the number of memory rows whose activation counts exceed the row-activation threshold.

Another example (e.g., example 5) relates to a previous example (e.g., one of the examples 1 to 4) or to any other example, further comprising that the method further comprises causing the memory device to refresh one or more victim memory rows adjacent to a memory row whose activation count exceeds the row-activation threshold for each targeted refresh command.

Another example (e.g., example 6) relates to a previous example (e.g., one of the examples 1 to 5) or to any other example, further comprising that the status value is received from the memory device during every second, third, or further periodic refresh command cycle that includes the indicator.

Another example (e.g., example 7) relates to a previous example (e.g., one of the examples 1 to 6) or to any other example, further comprising that the periodic refresh commands are issued at refresh intervals of below 5 microseconds.

Another example (e.g., example 8) relates to a previous example (e.g., one of the examples 1 to 7) or to any other example, further comprising that the memory device comprises a dynamic random-access memory device in which each memory region corresponds to a bank of the dynamic random-access memory device.

Another example (e.g., example 9) relates to a previous example (e.g., one of the examples 1 to 8) or to any other example, further comprising that the method further comprises transmitting the periodic refresh commands and the targeted refresh commands without increasing command bandwidth relative to standard refresh operation.

Another example (e.g., example 10) relates to a previous example (e.g., one of the examples 1 to 9) or to any other example, further comprising that the method further comprises refraining from processing a RowHammer-alert signal from the memory device.

Another example (e.g., example 11) relates to a previous example (e.g., one of the examples 1 to 10) or to any other example, further comprising that determining whether the targeted-refresh condition is satisfied is performed without maintaining activation counters for the memory regions at the one or more processing circuitries.

An example (e.g., example 12) relates to a memory device comprising a memory array organized into a plurality of memory regions, and control circuitry configured to perform periodic refresh operations on the plurality of memory regions in response to refresh commands received from a memory controller, wherein one or more of the refresh commands include an indicator requesting a status value, maintain, for each memory row within each memory region, an activation counter indicating a number of activations of that memory row, determine, for each memory region, the status value indicating a number of memory rows whose activation counters exceed a row-activation threshold, transmit the status value to the memory controller in response to receiving the one or more refresh commands including the indicator, and reset the status value of a memory region when one or more targeted refresh commands directed to that memory region are executed.

Another example (e.g., example 13) relates to a previous example (e.g., example 12) or to any other example, further comprising that the status value comprises, for each memory region, a multi-bit field representing a number of memory rows whose activation counters exceed the row-activation threshold.

Another example (e.g., example 14) relates to a previous example (e.g., example 13) or to any other example, further comprising that the multi-bit field comprises a two-bit field representing whether none, one, two, or three or more memory rows have activation counters exceeding the row-activation threshold.

Another example (e.g., example 15) relates to a previous example (e.g., one of the examples 12 to 14) or to any other example, further comprising that the control circuitry is further configured to transmit the status value to the memory controller only during every second, third, or further periodic refresh command cycle that includes the indicator.

Another example (e.g., example 16) relates to a previous example (e.g., one of the examples 12 to 15) or to any other example, further comprising that the control circuitry is further configured to increment each activation counter in response at least one of a row activation command or based on an open-row duration that exceeds a predetermined time.

Another example (e.g., example 17) relates to a previous example (e.g., one of the examples 12 to 16) or to any other example, further comprising that the control circuitry is further configured to perform, in response to a targeted refresh command, a targeted refresh of victim rows adjacent to a memory row whose activation counter exceeds the row-activation threshold.

Another example (e.g., example 18) relates to a previous example (e.g., one of the examples 12 to 17) or to any other example, further comprising that the control circuitry is further configured to omit transmission of a RowHammer-alert signal to the memory controller.

Another example (e.g., example 19) relates to a previous example (e.g., one of the examples 12 to 18) or to any other example, further comprising that the periodic refresh operations are executed at refresh intervals below 5 microseconds.

Another example (e.g., example 20) relates to a previous example (e.g., one of the examples 12 to 19) or to any other example, further comprising that the control circuitry is further configured to enable non-target on-die termination, NTODT, for a periodic refresh command that includes the indicator requesting the status value.

An example (e.g., example 21) relates to an apparatus comprising interface circuitry, and the apparatus further comprising machine-readable instructions and processing circuitry to execute the machine-readable instructions to issue periodic refresh commands to a memory device configured to perform refresh operations on a plurality of its memory regions, each memory region being a portion of the memory device comprising a plurality of memory rows, wherein at least one of the periodic refresh commands includes an indicator requesting a status value, receive, in response to the periodic refresh command including the indicator, the status value transmitted from the memory device, the status value indicating, for each memory region, a number of memory rows whose activation counts exceed a row-activation threshold, determine based on the status value whether a targeted-refresh condition is satisfied for one or more of the memory regions, and in response to determining that the targeted-refresh condition is satisfied for one or more memory regions, transmit, for each of the one or more memory regions, a number of targeted refresh commands to the memory device, the number being based on the status value of the corresponding memory region.

Another example (e.g., example 22) relates to a previous example (e.g., example 21) or to any other example, further comprising that the status value comprises, for each memory region, a multi-bit field representing a number of memory rows whose activation counts exceed the row-activation threshold.

Another example (e.g., example 23) relates to a previous example (e.g., example 22) or to any other example, further comprising that the multi-bit field comprises a two-bit field representing whether none, one, two, or three or more memory rows have activation counts exceeding the row-activation threshold.

Another example (e.g., example 24) relates to a previous example (e.g., one of the examples 21 to 23) or to any other example, further comprising that determining that the targeted-refresh condition is satisfied comprises identifying, based on the status value of each memory region, a number of targeted refresh commands to transmit to the memory device, the number being proportional to the number of memory rows whose activation counts exceed the row-activation threshold.

Another example (e.g., example 25) relates to a previous example (e.g., one of the examples 21 to 24) or to any other example, further comprising that the processing circuitry is further to execute the machine-readable instructions to cause the memory device to refresh one or more victim memory rows adjacent to a memory row whose activation count exceeds the row-activation threshold for each targeted refresh command.

Another example (e.g., example 26) relates to a previous example (e.g., one of the examples 21 to 25) or to any other example, further comprising that the status value is received from the memory device during every second, third, or further periodic refresh command cycle that includes the indicator.

Another example (e.g., example 27) relates to a previous example (e.g., one of the examples 21 to 26) or to any other example, further comprising that the periodic refresh commands are issued at refresh intervals of below 5 microseconds.

Another example (e.g., example 28) relates to a previous example (e.g., one of the examples 21 to 27) or to any other example, further comprising that the memory device comprises a dynamic random-access memory device in which each memory region corresponds to a bank of the dynamic random-access memory device.

Another example (e.g., example 29) relates to a previous example (e.g., one of the examples 21 to 28) or to any other example, further comprising that the processing circuitry is further to execute the machine-readable instructions to transmit the periodic refresh commands and the targeted refresh commands without increasing command bandwidth relative to standard refresh operation.

Another example (e.g., example 30) relates to a previous example (e.g., one of the examples 21 to 29) or to any other example, further comprising that the processing circuitry is further to execute the machine-readable instructions to refrain from processing a RowHammer-alert signal from the memory device.

Another example (e.g., example 31) relates to a previous example (e.g., one of the examples 21 to 30) or to any other example, further comprising that determining whether the targeted-refresh condition is satisfied is performed without maintaining activation counters for the memory regions at the processing circuitry.

An example (e.g., example 32) relates to a method comprising issuing periodic refresh commands to a memory device configured to perform refresh operations on a plurality of its memory regions, each memory region being a portion of the memory device comprising a plurality of memory rows, wherein at least one of the periodic refresh commands includes an indicator requesting a status value, receiving, in response to the periodic refresh command including the indicator, the status value transmitted from the memory device, the status value indicating, for each memory region, a number of memory rows whose activation counts exceed a row-activation threshold, determining based on the status value whether a targeted-refresh condition is satisfied for one or more of the memory regions, and in response to determining that the targeted-refresh condition is satisfied for one or more memory regions, transmitting, for each of the one or more memory regions, a number of targeted refresh commands to the memory device, the number being based on the status value of the corresponding memory region.

Another example relates to a previous example (e.g., example 32) or to any other example, further comprising that the status value comprises, for each memory region, a multi-bit field representing a number of memory rows whose activation counts exceed the row-activation threshold.

Another example relates to a previous example (e.g., example 33) or to any other example, further comprising that the multi-bit field comprises a two-bit field representing whether none, one, two, or three or more memory rows have activation counts exceeding the row-activation threshold.

Another example (e.g., example 33) relates to a previous example (e.g., one of the examples 32 to 34) or to any other example, further comprising that determining that the targeted-refresh condition is satisfied comprises identifying, based on the status value of each memory region, a number of targeted refresh commands to transmit to the memory device, the number being proportional to the number of memory rows whose activation counts exceed the row-activation threshold.

Another example (e.g., example 34) relates to a previous example (e.g., one of the examples 32 to 35) or to any other example, further comprising causing the memory device to refresh one or more victim memory rows adjacent to a memory row whose activation count exceeds the row-activation threshold for each targeted refresh command.

Another example (e.g., example 35) relates to a previous example (e.g., one of the examples 32 to 36) or to any other example, further comprising that the status value is received from the memory device during every second, third, or further periodic refresh command cycle that includes the indicator.

Another example (e.g., example 36) relates to a previous example (e.g., one of the examples 32 to 37) or to any other example, further comprising that the periodic refresh commands are issued at refresh intervals of below 5 microseconds.

Another example (e.g., example 37) relates to a previous example (e.g., one of the examples 32 to 38) or to any other example, further comprising that the memory device comprises a dynamic random-access memory device in which each memory region corresponds to a bank of the dynamic random-access memory device.

Another example (e.g., example 38) relates to a previous example (e.g., one of the examples 32 to 39) or to any other example, further comprising transmitting the periodic refresh commands and the targeted refresh commands without increasing command bandwidth relative to standard refresh operation.

Another example (e.g., example 39) relates to a previous example (e.g., one of the examples 32 to 40) or to any other example, further comprising refraining from processing a RowHammer-alert signal from the memory device.

Another example (e.g., example 40) relates to a previous example (e.g., one of the examples 32 to 41) or to any other example, further comprising that determining whether the targeted-refresh condition is satisfied is performed without maintaining activation counters for the memory regions.

An example (e.g., example 41) relates to an apparatus comprising a processor circuitry configured to issue periodic refresh commands to a memory device configured to perform refresh operations on a plurality of its memory regions, each memory region being a portion of the memory device comprising a plurality of memory rows, wherein at least one of the periodic refresh commands includes an indicator requesting a status value, receive, in response to the periodic refresh command including the indicator, the status value transmitted from the memory device, the status value indicating, for each memory region, a number of memory rows whose activation counts exceed a row-activation threshold, determine based on the status value whether a targeted-refresh condition is satisfied for one or more of the memory regions, and in response to determining that the targeted-refresh condition is satisfied for one or more memory regions, transmit, for each of the one or more memory regions, a number of targeted refresh commands to the memory device, the number being based on the status value of the corresponding memory region.

An example (e.g., example 42) relates to a device comprising means for processing for issuing periodic refresh commands to a memory device configured to perform refresh operations on a plurality of its memory regions, each memory region being a portion of the memory device comprising a plurality of memory rows, wherein at least one of the periodic refresh commands includes an indicator requesting a status value, receiving, in response to the periodic refresh command including the indicator, the status value transmitted from the memory device, the status value indicating, for each memory region, a number of memory rows whose activation counts exceed a row-activation threshold, determining based on the status value whether a targeted-refresh condition is satisfied for one or more of the memory regions, and in response to determining that the targeted-refresh condition is satisfied for one or more memory regions, transmitting, for each of the one or more memory regions, a number of targeted refresh commands to the memory device, the number being based on the status value of the corresponding memory region.

Another example (e.g., example 43) relates to a computer program having a program code for performing the method of any one of examples 32 to 42 when the computer program is executed on a computer, a processor, or a programmable hardware component.

An example (e.g., example 44) relates to a method comprising performing periodic refresh operations on a plurality of memory regions of a memory array in response to refresh commands received from a memory controller, wherein one or more of the refresh commands include an indicator requesting a status value, maintaining, for each memory row within each memory region, an activation counter indicating a number of activations of that memory row, determining, for each memory region, the status value indicating a number of memory rows whose activation counters exceed a row-activation threshold, transmitting the status value to the memory controller in response to receiving the one or more refresh commands including the indicator, and resetting the status value of a memory region when one or more targeted refresh commands directed to that memory region are executed.

Another example (e.g., example 45) relates to a previous example (e.g., example 44) or to any other example, further comprising that the status value comprises, for each memory region, a multi-bit field representing a number of memory rows whose activation counters exceed the row-activation threshold.

Another example (e.g., example 46) relates to a previous example (e.g., example 45) or to any other example, further comprising that the multi-bit field comprises a two-bit field representing whether none, one, two, or three or more memory rows have activation counters exceeding the row-activation threshold.

Another example (e.g., example 47) relates to a previous example (e.g., one of the examples 44 to 46) or to any other example, further comprising transmitting the status value to the memory controller only during every second, third, or further periodic refresh command cycle that includes the indicator.

Another example (e.g., example 48) relates to a previous example (e.g., one of the examples 44 to 47) or to any other example, further comprising incrementing each activation counter in response to at least one of a row activation command or based on an open-row duration that exceeds a predetermined time.

Another example (e.g., example 49) relates to a previous example (e.g., one of the examples 44 to 48) or to any other example, further comprising performing, in response to a targeted refresh command, a targeted refresh of victim rows adjacent to a memory row whose activation counter exceeds the row-activation threshold.

Another example (e.g., example 50) relates to a previous example (e.g., one of the examples 44 to 49) or to any other example, further comprising omitting transmission of a RowHammer-alert signal to the memory controller.

Another example (e.g., example 51) relates to a previous example (e.g., one of the examples 44 to 50) or to any other example, further comprising that the periodic refresh operations are executed at refresh intervals below 5 microseconds.

Another example (e.g., example 52) relates to a previous example (e.g., one of the examples 44 to 51) or to any other example, further comprising enabling non-target on-die termination, NTODT, for a periodic refresh command that includes the indicator requesting the status value.

An example (e.g., example 53) relates to a memory device comprising a memory array organized into a plurality of memory regions, and processor circuitry configured to perform periodic refresh operations on the plurality of memory regions in response to refresh commands received from a memory controller, wherein one or more of the refresh commands include an indicator requesting a status value, maintain, for each memory row within each memory region, an activation counter indicating a number of activations of that memory row, determine, for each memory region, the status value indicating a number of memory rows whose activation counters exceed a row-activation threshold, transmit the status value to the memory controller in response to receiving the one or more refresh commands including the indicator, and reset the status value of a memory region when one or more targeted refresh commands directed to that memory region are executed.

An example (e.g., example 54) relates to a memory device comprising a memory array organized into a plurality of memory regions, and means for processing for performing periodic refresh operations on the plurality of memory regions in response to refresh commands received from a memory controller, wherein one or more of the refresh commands include an indicator requesting a status value, maintaining, for each memory row within each memory region, an activation counter indicating a number of activations of that memory row, determining, for each memory region, the status value indicating a number of memory rows whose activation counters exceed a row-activation threshold, transmitting the status value to the memory controller in response to receiving the one or more refresh commands including the indicator, and resetting the status value of a memory region when one or more targeted refresh commands directed to that memory region are executed.

Another example (e.g., example 55) relates to a computer program having a program code for performing the method of any one of examples 44 to 52 when the computer program is executed on a computer, a processor, or a programmable hardware component.

An example (e.g., example 56) relates to a memory device, comprising a plurality of memory rows organized within a memory bank, and control circuitry configured to maintain a per-row activation counter for each of the plurality of memory rows, execute a periodic refresh sequence on the memory bank, wherein the refresh sequence is non-sequential and comprises, for a designated aggressor row, refreshing one or more victim rows associated with the designated aggressor row prior to refreshing the designated aggressor row, monitor for an activation of the designated aggressor row during a monitoring period corresponding to the refresh of its one or more associated victim rows, and in response to completing the refresh of the designated aggressor row, and based on determining that no activation of the designated aggressor row occurred during the monitoring period, resetting the per-row activation counter of the designated aggressor row.

Another example (e.g., example 57) relates to a previous example (e.g., example 56) or to any other example, further comprising that the control circuitry is further configured to, when an activation of the designated aggressor row occurs during the monitoring period, store an activation count value of the designated aggressor row when the designated aggressor row is activated for the first time during the monitoring period, and subtract the stored value from the per-row activation counter following completion of the refresh of the designated aggressor row.

Another example (e.g., example 58) relates to a previous example (e.g., one of the examples 56 to 57) or to any other example, further comprising that the control circuitry is configured to monitor for the activation by maintaining one or more Boolean flags, wherein a flag is set to indicate an activation of its corresponding designated aggressor row during the monitoring period.

Another example (e.g., example 59) relates to a previous example (e.g., example 58) or to any other example, further comprising that the control circuitry is configured to set the one or more Boolean flags by receiving an activate command, calculating a difference between a row address in the activate command and a current refresh row address, and updating a specific flag based on the calculated difference.

Another example (e.g., example 60) relates to a previous example (e.g., one of the examples 56 to 59) or to any other example, further comprising that the non-sequential refresh sequence comprises refreshing a first victim row at a first offset from the designated aggressor row, followed by refreshing a second victim row at a second offset from the designated aggressor row, prior to refreshing the designated aggressor row.

Another example (e.g., example 61) relates to a previous example (e.g., one of the examples 56 to 60) or to any other example, further comprising that resetting the per-row activation counter comprises setting the counter to a value lower than its value prior to the reset.

Another example (e.g., example 62) relates to a previous example (e.g., example 61) or to any other example, further comprising that the value to which the per-row activation counter value is set is less than or equal to thirty-two.

Another example (e.g., example 63) relates to method comprising maintaining a per-row activation counter for each of a plurality of memory rows organized within a memory bank, executing a periodic refresh sequence on the memory bank, wherein the refresh sequence is non-sequential and comprises, for a designated aggressor row, refreshing one or more victim rows associated with the designated aggressor row prior to refreshing the designated aggressor row, monitoring for an activation of the designated aggressor row during a monitoring period corresponding to the refresh of its one or more associated victim rows, and in response to completing the refresh of the designated aggressor row, and based on determining that no activation of the designated aggressor row occurred during the monitoring period, resetting the per-row activation counter of the designated aggressor row.

Another example (e.g., example 64) relates to a previous example (e.g., example 63) or to any other example, further comprising when an activation of the designated aggressor row occurs during the monitoring period, storing an activation count value of the designated aggressor row when the designated aggressor row is activated for the first time during the monitoring period, and subtracting the stored value from the per-row activation counter following completion of the refresh of the designated aggressor row.

Another example (e.g., example 65) relates to a previous example (e.g., one of the examples 63 to 64) or to any other example, further comprising that monitoring for the activation comprises maintaining one or more Boolean flags, wherein a flag is set to indicate an activation of its corresponding designated aggressor row during the monitoring period.

Another example (e.g., example 66) relates to a previous example (e.g., example 65) or to any other example, further comprising that setting the one or more Boolean flags comprises receiving an activate command, calculating a difference between a row address in the activate command and a current refresh row address, and updating a specific flag based on the calculated difference.

Another example (e.g., example 67) relates to a previous example (e.g., one of the examples 63 to 66) or to any other example, further comprising that the non-sequential refresh sequence comprises refreshing a first victim row at a first offset from the designated aggressor row, followed by refreshing a second victim row at a second offset from the designated aggressor row, prior to refreshing the designated aggressor row.

Another example (e.g., example 68) relates to a previous example (e.g., one of the examples 63 to 67) or to any other example, further comprising that resetting the per-row activation counter comprises setting the counter to a value lower than its value prior to the reset.

Another example (e.g., example 69) relates to a previous example (e.g., example 68) or to any other example, further comprising that the value to which the per-row activation counter value is set is less than or equal to thirty-two.

An example (e.g., example 70) relates to a memory device, comprising a plurality of memory rows organized within a memory bank, and processor circuitry configured to maintain a per-row activation counter for each of the plurality of memory rows, execute a periodic refresh sequence on the memory bank, wherein the refresh sequence is non-sequential and comprises, for a designated aggressor row, refreshing one or more victim rows associated with the designated aggressor row prior to refreshing the designated aggressor row, monitor for an activation of the designated aggressor row during a monitoring period corresponding to the refresh of its one or more associated victim rows, and in response to completing the refresh of the designated aggressor row, and based on determining that no activation of the designated aggressor row occurred during the monitoring period, reset the per-row activation counter of the designated aggressor row.

An example (e.g., example 71) relates to a memory device, comprising a plurality of memory rows organized within a memory bank, and means for processing for maintaining a per-row activation counter for each of the plurality of memory rows, executing a periodic refresh sequence on the memory bank, wherein the refresh sequence is non-sequential and comprises, for a designated aggressor row, refreshing one or more victim rows associated with the designated aggressor row prior to refreshing the designated aggressor row, monitoring for an activation of the designated aggressor row during a monitoring period corresponding to the refresh of its one or more associated victim rows, and in response to completing the refresh of the designated aggressor row, and based on determining that no activation of the designated aggressor row occurred during the monitoring period, resetting the per-row activation counter of the designated aggressor row.

Another example (e.g., example 72) relates to a computer program having a program code for performing the method of any one of examples 63 to 69 when the computer program is executed on a computer, a processor, or a programmable hardware component.

An example (e.g., example 73) relates to a memory device, comprising a memory array comprising a plurality of memory rows and a control circuitry configured to maintain a per-row activation counter for each of the plurality of memory rows within the memory array, in response to detecting that a per-row activation counter for a designated aggressor row has reached a threshold store an identifier of the designated aggressor row and its corresponding counter value in a service queue, and reset the per-row activation counter for the designated aggressor row in the memory array, and in response to subsequently receiving a targeted refresh command associated with the designated aggressor row perform one or more refresh operations on one or more victim rows associated with the designated aggressor row, and omit performing a refresh operation on the designated aggressor row.

Another example (e.g., example 74) relates to a previous example (e.g., example 73) or to any other example, further comprising that the control circuitry is configured to detect that the threshold has been reached during a precharge command for the designated aggressor row.

Another example (e.g., example 75) relates to a previous example (e.g., one of the examples 73 to 74) or to any other example, further comprising that resetting the per-row activation counter in the memory array comprises setting the counter to a value lower than its value prior to the reset.

Another example (e.g., example 76) relates to a previous example (e.g., example 75) or to any other example, further comprising that the value to which the per-row activation counter is set is value less than or equal to thirty-two.

Another example (e.g., example 77) relates to a previous example (e.g., one of the examples 73 to 76) or to any other example, further comprising that the service queue is configured to store, for each entry, both the row identifier and the corresponding counter value.

An example (e.g., example 78) relates to a method comprising maintaining a per-row activation counter for each of a plurality of memory rows within a memory array, in response to detecting that a per-row activation counter for a designated aggressor row has reached a threshold storing an identifier of the designated aggressor row and its corresponding counter value in a service queue, and resetting the per-row activation counter for the designated aggressor row in the memory array, and in response to subsequently receiving a targeted refresh command associated with the designated aggressor row performing one or more refresh operations on one or more victim rows associated with the designated aggressor row, and omitting performing a refresh operation on the designated aggressor row.

Another example (e.g., example 79) relates to a previous example (e.g., example 78) or to any other example, further comprising that detecting that the threshold has been reached occurs during a precharge command for the designated aggressor row.

Another example (e.g., example 80) relates to a previous example (e.g., one of the examples 78 to 79) or to any other example, further comprising that resetting the per-row activation counter in the memory array comprises setting the counter to a value lower than its value prior to the reset.

Another example (e.g., example 81) relates to a previous example (e.g., example 80) or to any other example, further comprising that the value to which the per-row activation counter is set is less than or equal to thirty-two.

Another example (e.g., example 82) relates to a previous example (e.g., one of the examples 78 to 81) or to any other example, further comprising that the service queue stores, for each entry, both the row identifier and the corresponding counter value.

An example (e.g., example 83) relates to a memory device, comprising a memory array comprising a plurality of memory rows and processor circuitry configured to maintain a per-row activation counter for each of the plurality of memory rows within the memory array, in response to detecting that a per-row activation counter for a designated aggressor row has reached a threshold store an identifier of the designated aggressor row and its corresponding counter value in a service queue, and reset the per-row activation counter for the designated aggressor row in the memory array, and in response to subsequently receiving a targeted refresh command associated with the designated aggressor row perform one or more refresh operations on one or more victim rows associated with the designated aggressor row, and omit performing a refresh operation on the designated aggressor row.

An example (e.g., example 84) relates to a memory device, comprising a memory array comprising a plurality of memory rows and means for processing for maintaining a per-row activation counter for each of the plurality of memory rows within the memory array, in response to detecting that a per-row activation counter for a designated aggressor row has reached a threshold storing an identifier of the designated aggressor row and its corresponding counter value in a service queue, and resetting the per-row activation counter for the designated aggressor row in the memory array, and in response to subsequently receiving a targeted refresh command associated with the designated aggressor row performing one or more refresh operations on one or more victim rows associated with the designated aggressor row, and omitting performing a refresh operation on the designated aggressor row.

Another example (e.g., example 85) relates to a computer program having a program code for performing the method of any one of examples 78 to 82 when the computer program is executed on a computer, a processor, or a programmable hardware component.

An example (e.g., example 86) relates to a memory device, comprising a memory array comprising a plurality of memory rows and a control circuitry configured to in response to detecting that a per-row activation counter for a designated aggressor row has reached a threshold store an identifier of the designated aggressor row in a service queue, and associate a mitigation state with the identifier, the mitigation state being initialized to a first state, in response to receiving a first periodic refresh command while the identifier is in the service queue and the mitigation state is the first state perform a first portion of a targeted refresh operation by refreshing a first subset of victim rows associated with the designated aggressor row, and update the mitigation state in the service queue to a second state, and in response to receiving a second periodic refresh command while the identifier is in the service queue and the mitigation state is the second state perform a second portion of the targeted refresh operation by refreshing a second subset of victim rows associated with the designated aggressor row.

Another example (e.g., example 87) relates to a previous example (e.g., example 86) or to any other example, further comprising that the control circuitry is further configured to, in response to detecting the threshold, store a counter value in the service queue and reset the per-row activation counter in the memory array a value lower than its value prior to the reset.

Another example (e.g., example 88) relates to a previous example (e.g., example 87) or to any other example, further comprising that the value to which the per-row activation counter is set is value less than or equal to thirty-two.

Another example (e.g., example 89) relates to a previous example (e.g., one of the examples 86 to 88) or to any other example, further comprising that the control circuitry is further configured to, in response to an activation of the designated aggressor row while the mitigation state is the second state, increment a counter value stored in the service queue and increment the per-row activation counter in the memory array.

Another example (e.g., example 90) relates to a previous example (e.g., one of the examples 86 to 89) or to any other example, further comprising that the first subset of victim rows comprises rows at a first offset, and the second subset of victim rows comprises rows at a second offset.

Another example (e.g., example 91) relates to a previous example (e.g., one of the examples 86 to 90) or to any other example, further comprising that the first state is an awaiting mitigation state and the second state is a partially complete state. In some examples, there may be further states.

An example (e.g., example 92) relates to a method comprising in response to detecting that a per-row activation counter for a designated aggressor row has reached a threshold storing an identifier of the designated aggressor row in a service queue, and associating a mitigation state with the identifier, the mitigation state being initialized to a first state, in response to receiving a first periodic refresh command while the identifier is in the service queue and the mitigation state is the first state performing a first portion of a targeted refresh operation by refreshing a first subset of victim rows associated with the designated aggressor row, and updating the mitigation state in the service queue to a second state, and in response to receiving a second periodic refresh command while the identifier is in the service queue and the mitigation state is the second state performing a second portion of the targeted refresh operation by refreshing a second subset of victim rows associated with the designated aggressor row.

Another example (e.g., example 93) relates to a previous example (e.g., example 92) or to any other example, further comprising in response to detecting the threshold, storing a counter value in the service queue and resetting the per-row activation counter in a memory array to a value lower than its value prior to the reset.

Another example (e.g., example 94) relates to a previous example (e.g., example 93) or to any other example, further comprising that the value to which the per-row activation counter is set is less than or equal to thirty-two.

Another example (e.g., example 95) relates to a previous example (e.g., one of the examples 92 to 94) or to any other example, further comprising in response to an activation of the designated aggressor row while the mitigation state is the second state, incrementing a counter value stored in the service queue and incrementing the per-row activation counter in the memory array.

Another example (e.g., example 96) relates to a previous example (e.g., one of the examples 92 to 95) or to any other example, further comprising that the first subset of victim rows comprises rows at a first offset, and the second subset of victim rows comprises rows at a second offset.

Another example (e.g., example 97) relates to a previous example (e.g., one of the examples 92 to 96) or to any other example, further comprising that the first state is an awaiting mitigation state and the second state is a partially complete state.

An example (e.g., example 98) relates to a memory device, comprising a memory array comprising a plurality of memory rows and processor circuitry configured to in response to detecting that a per-row activation counter for a designated aggressor row has reached a threshold store an identifier of the designated aggressor row in a service queue, and associate a mitigation state with the identifier, the mitigation state being initialized to a first state, in response to receiving a first periodic refresh command while the identifier is in the service queue and the mitigation state is the first state perform a first portion of a targeted refresh operation by refreshing a first subset of victim rows associated with the designated aggressor row, and update the mitigation state in the service queue to a second state, and in response to receiving a second periodic refresh command while the identifier is in the service queue and the mitigation state is the second state perform a second portion of the targeted refresh operation by refreshing a second subset of victim rows associated with the designated aggressor row.

An example (e.g., example 99) relates to a memory device, comprising a memory array comprising a plurality of memory rows and means for processing for in response to detecting that a per-row activation counter for a designated aggressor row has reached a threshold storing an identifier of the designated aggressor row in a service queue, and associating a mitigation state with the identifier, the mitigation state being initialized to a first state, in response to receiving a first periodic refresh command while the identifier is in the service queue and the mitigation state is the first state performing a first portion of a targeted refresh operation by refreshing a first subset of victim rows associated with the designated aggressor row, and updating the mitigation state in the service queue to a second state, and in response to receiving a second periodic refresh command while the identifier is in the service queue and the mitigation state is the second state performing a second portion of the targeted refresh operation by refreshing a second subset of victim rows associated with the designated aggressor row.

Another example (e.g., example 100) relates to a computer program having a program code for performing the method of any one of examples 92 to 97 when the computer program is executed on a computer, a processor, or a programmable hardware component.

Another example (e.g., example 101) relates to a machine-readable storage including machine readable instructions, when executed, to implement a method or realize an apparatus as claimed in any pending example

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

As used herein, the term “module” refers to logic that may be implemented in a hardware component or device, software or firmware running on a processing unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processing units, state machine circuitry, and/or firmware that stores instructions executable by programmable circuitry. Modules described herein may, collectively or individually, be embodied as circuitry that forms a part of a computing system. Thus, any of the modules can be implemented as circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processing units capable of executing computer-executable instructions to perform any of the disclosed methods. As used herein, the term “computer” refers to any computing system or device described or mentioned herein. Thus, the term “computer-executable instruction” refers to instructions that can be executed by any computing system or device described or mentioned herein.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based examples (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

The disclosed methods, apparatuses, and systems are not to be construed as limiting in any way. Instead, the present disclosure is directed toward all novel and nonobvious features and aspects of the various disclosed examples, alone and in various combinations and subcombinations with one another. The disclosed methods, apparatuses, and systems are not limited to any specific aspect or feature or combination thereof, nor do the disclosed examples require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. A memory device comprising a non-transitory computer-readable medium storing instructions that, when executed by one or more processing circuitries, cause the one or more processing circuitries to perform a method comprising:
issuing periodic refresh commands to a memory device configured to perform refresh operations on a plurality of its memory regions, each memory region being a portion of the memory device comprising a plurality of memory rows, wherein at least one of the periodic refresh commands includes an indicator requesting a status value;
receiving, in response to the periodic refresh command including the indicator, the status value transmitted from the memory device, the status value indicating, for each memory region, a number of memory rows whose activation counts exceed a row-activation threshold;
determining based on the status value whether a targeted-refresh condition is satisfied for one or more of the memory regions; and
in response to determining that the targeted-refresh condition is satisfied for one or more memory regions, transmitting, for each of the one or more memory regions, a number of targeted refresh commands to the memory device, the number being based on the status value of the corresponding memory region.

2. The computer-readable medium of claim 1, wherein the status value comprises, for each memory region, a multi-bit field representing a number of memory rows whose activation counts exceed the row-activation threshold.

3. The computer-readable medium of claim 2, wherein the multi-bit field comprises a two-bit field representing whether none, one, two, or three or more memory rows have activation counts exceeding the row-activation threshold.

4. The computer-readable medium of claim 1, wherein determining that the targeted-refresh condition is satisfied comprises identifying, based on the status value of each memory region, a number of targeted refresh commands to transmit to the memory device, the number being proportional to the number of memory rows whose activation counts exceed the row-activation threshold.

5. The computer-readable medium of claim 1, wherein the method further comprises causing the memory device to refresh one or more victim memory rows adjacent to a memory row whose activation count exceeds the row-activation threshold for each targeted refresh command.

6. The computer-readable medium of claim 1, wherein the status value is received from the memory device during every second, third, or further periodic refresh command cycle that includes the indicator.

7. The computer-readable medium of claim 1, wherein the periodic refresh commands are issued at refresh intervals of below 5 microseconds.

8. The computer-readable medium of claim 1, wherein the memory device comprises a dynamic random-access memory device in which each memory region corresponds to a bank of the dynamic random-access memory device.

9. The computer-readable medium of claim 1, wherein the method further comprises transmitting the periodic refresh commands and the targeted refresh commands without increasing command bandwidth relative to standard refresh operation.

10. The computer-readable medium of claim 1, wherein the method further comprises refraining from processing a RowHammer-alert signal from the memory device.

11. The computer-readable medium of claim 1, wherein determining whether the targeted-refresh condition is satisfied is performed without maintaining activation counters for the memory regions at the one or more processing circuitries.

12. A memory device comprising a memory array organized into a plurality of memory regions, and control circuitry configured to:
perform periodic refresh operations on the plurality of memory regions in response to refresh commands received from a memory controller, wherein one or more of the refresh commands include an indicator requesting a status value;
maintain, for each memory row within each memory region, an activation counter indicating a number of activations of that memory row;
determine, for each memory region, the status value indicating a number of memory rows whose activation counters exceed a row-activation threshold;
transmit the status value to the memory controller in response to receiving the one or more refresh commands including the indicator; and
reset the status value of a memory region when one or more targeted refresh commands directed to that memory region are executed.

13. The memory device of claim 12, wherein the status value comprises, for each memory region, a multi-bit field representing a number of memory rows whose activation counters exceed the row-activation threshold.

14. The memory device of claim 13, wherein the multi-bit field comprises a two-bit field representing whether none, one, two, or three or more memory rows have activation counters exceeding the row-activation threshold.

15. The memory device of claim 12, wherein the control circuitry is further configured to transmit the status value to the memory controller only during every second, third, or further periodic refresh command cycle that includes the indicator.

16. The memory device of claim 12, wherein the control circuitry is further configured to increment each activation counter in response at least one of a row activation command or based on an open-row duration that exceeds a predetermined time.

17. The memory device of claim 12, wherein the control circuitry is further configured to perform, in response to a targeted refresh command, a targeted refresh of victim rows adjacent to a memory row whose activation counter exceeds the row-activation threshold.

18. The memory device of claim 12, wherein the control circuitry is further configured to omit transmission of a RowHammer-alert signal to the memory controller.

19. The memory device of claim 12, wherein the periodic refresh operations are executed at refresh intervals below 5 microseconds.

20. The memory device of claim 12, wherein the control circuitry is further configured to enable non-target on-die termination, NTODT, for a periodic refresh command that includes the indicator requesting the status value.
